(19) United States
(12) Patent Application Publication
(10) Pub. No.: US 2024/0188293 A1
(43) Pub. Date: Jun. 6, 2024

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Sam Ki KIM, Suwon-si (KR); Nam Bin KIM, Suwon-si (KR); Ji Woong KIM, Suwon-si (KR); Tae Hun KIM, Suwon-si (KR); Ki Bong MOON, Suwon-si (KR); Sae Rom LEE, Suwon-si (KR); Sung-Bok LEE, Suwon-si (KR); Jun Hee LIM, Suwon-si (KR); Nag Yong CHOI, Suwon-si (KR); Sun Gyung HWANG, Suwon-si (KR)

(21) Appl. No.: 18/229,296

(22) Filed: Aug. 2, 2023

(30) Foreign Application Priority Data
Dec. 2, 2022 (KR) 10-2022-0166848

(51) Int. Cl. H10B 43/27; H10B 43/40

(52) U.S. Cl. CPC H10B 43/27; H10B 43/40

(57) ABSTRACT

A semiconductor memory device including a substrate; a mold structure including gate electrodes and mold insulating layers stacked in a stair shape, channel structures on the substrate, intersecting the gate electrodes, and passing through the mold structure; cell contacts connected to the gate electrodes; a first interlayer insulating layer on the mold structure and covering the channel structures and cell contacts; first metal patterns connected to the channel structures, an upper surface of the first metal patterns being coplanar with an upper surface of the first interlayer insulating layer; second metal patterns connected to the cell contacts, an upper surface of the second metal patterns being coplanar with the upper surface of the first metal patterns; a first blocking layer along the upper surface of the first interlayer insulating layer, the first metal patterns, and the second metal patterns; and a first dummy vias passing through the first blocking layer.

### CROSS-REFERENCE TO RELATED APPLICATION

This application claims priority from Korean Patent Application No. 10-2022-0166848 filed on Dec. 2, 2022, in the Korean Intellectual Property Office and all the benefits accruing therefrom under 35 U.S.C. § 119, the contents of which in its entirety are herein incorporated by reference.

### BACKGROUND

### 1. Field

Embodiments relate to a semiconductor memory device and an electronic system including the same and an electronic system including the same.

### 2. Description of the Related Art

The degree of integration of a non-volatile memory device may be increased to fulfil excellent performance and low cost, which are required by consumers. In case of the non-volatile memory device, the degree of integration may be an important factor that determines the price of a product, and the increased degree of integration has been considered.

In a two-dimensional or planar non-volatile memory device, the degree of integration may be mainly determined by an area occupied by a unit memory cell, and it may be greatly affected by the level of the technology for forming a fine pattern. Ultra-high-priced equipment may be used for the fine pattern, and the degree of integration of the two-dimensional non-volatile memory device is increasing but is still restrictive. Therefore, three-dimensional non-volatile memory devices including memory cells that are arranged three-dimensionally have been considered.

### SUMMARY

The embodiments may be realized by providing a semiconductor memory device including a substrate including a cell array region and an extension region; a mold structure including a plurality of gate electrodes sequentially stacked on the cell array region and the extension region of the substrate in a stair shape, and a plurality of mold insulating layers stacked alternately with the plurality of gate electrodes; a plurality of channel structures on the cell array region of the substrate, the plurality of channel structures intersecting the plurality of gate electrodes and passing through the mold structure; a plurality of cell contacts respectively connected to the plurality of gate electrodes on the extension region of the substrate; a first interlayer insulating layer on the mold structure and covering the plurality of channel structures and the plurality of cell contacts; a plurality of first metal patterns respectively connected to the plurality of channel structures, an upper surface of the plurality of first metal patterns being coplanar with an upper surface of the first interlayer insulating layer; a plurality of second metal patterns respectively connected to the plurality of cell contacts, an upper surface of the plurality of second metal patterns being coplanar with the upper surface of the plurality of first metal patterns; a first blocking layer extending along the upper surface of the first interlayer insulating layer, the upper surface of the plurality of first metal patterns, and the upper surface of the plurality of second metal patterns; and a plurality of first dummy vias passing through the first blocking layer.

The embodiments may be realized by providing a semiconductor memory device including a peripheral circuit structure including a peripheral circuit element; and a cell structure on the peripheral circuit structure, wherein the cell structure includes a substrate including a cell array region, an extension region, and a pad region; a mold structure including a plurality of gate electrodes sequentially stacked on the cell array region and the extension region of the substrate in a stair shape, and a plurality of mold insulating layers stacked alternately with the plurality of gate electrodes; a plurality of channel structures on the cell array region of the substrate, the plurality of channel structures intersecting the plurality of gate electrodes and passing through the mold structure; a plurality of cell contacts respectively connected to the plurality of gate electrodes on the extension region of the substrate; a first interlayer insulating layer on the mold structure and covering the plurality of channel structures and the plurality of cell contacts; a through contact on the pad region of the substrate and connected to the peripheral circuit element by passing through the first interlayer insulating layer; a plurality of first metal patterns respectively connected to the plurality of channel structures, an upper surface of the plurality of first metal patterns being coplanar with an upper surface of the first interlayer insulating layer; a plurality of second metal patterns respectively connected to the plurality of cell contacts, an upper surface of the plurality of second metal patterns being coplanar with the upper surface of the plurality of first metal patterns; a third metal pattern connected to the through contact, an upper surface of the third metal pattern being coplanar with the upper surface of the plurality of first metal patterns; a first blocking layer extending along the upper surface of the first interlayer insulating layer, the upper surface of the plurality of first metal patterns, the upper surface of the plurality of second metal patterns, and the upper surface of the third metal pattern; a second interlayer insulating layer on the first blocking layer; a plurality of fourth metal patterns in the second interlayer insulating layer, an upper surface of the plurality of fourth metal patterns being coplanar with an upper surface of the second interlayer insulating layer; a plurality of vias below the plurality of fourth metal patterns and connected to the plurality of first metal patterns, the plurality of second metal patterns, and the third metal pattern; a second blocking layer on the second interlayer insulating layer; a plurality of first dummy vias passing through the first blocking layer, on the pad region of the substrate and the extension region of the substrate and not on the cell array region of the substrate; and a plurality of second dummy vias passing through the first blocking layer, and wherein at least a portion of the plurality of first dummy vias is in the first interlayer insulating layer and in the second interlayer insulating layer.

The embodiments may be realized by providing an electronic system including a main board; a semiconductor memory device on the main board; and a controller electrically connected to the semiconductor memory device on the main board, wherein the semiconductor memory device includes a substrate including a cell array region and an extension region; a mold structure including a plurality of gate electrodes sequentially stacked on the cell array region and the extension region of the substrate in a stair shape, and a plurality of mold insulating layers stacked alternately with the plurality of gate electrodes; a plurality of channel structures on the cell array region of the substrate and intersecting the plurality of gate electrodes by passing through the mold structure; a plurality of cell contacts respectively connected to the plurality of gate electrodes on the substrate of the extension region; a first interlayer insulating layer on the mold structure and covering the plurality of channel structures and the plurality of cell contacts; a plurality of first metal patterns respectively connected to the plurality of channel structures, an upper surface of the plurality of first metal patterns being coplanar with an upper surface of the first interlayer insulating layer; a plurality of second metal patterns respectively connected to the plurality of cell contacts, an upper surface of the plurality of second metal patterns being coplanar with the upper surface of the plurality of first metal patterns; a first blocking layer extended along the upper surface of the first interlayer insulating layer, the upper surface of the plurality of first metal patterns and the upper surface of the plurality of second metal patterns; and a plurality of first dummy vias passing through the first blocking layer.

### BRIEF DESCRIPTION OF DRAWINGS

Features will be apparent to those of skill in the art by describing in detail exemplary embodiments with reference to the attached drawings in which:

FIG. 1 is an exemplary block diagram illustrating a semiconductor memory device according to some embodiments.

FIG. 2 is an exemplary circuit view illustrating a semiconductor memory device according to some embodiments.

FIG. 3 is an exemplary cross-sectional view illustrating a semiconductor memory device according to some embodiments.

FIG. 4 is an enlarged view illustrating a region P1 of FIG. 3.

FIG. 5 is an enlarged view illustrating a region P2 of FIG. 3.

FIG. 6 is an enlarged view illustrating a region Q1 of FIG. 3.

FIG. 7 is an exemplary cross-sectional view illustrating a semiconductor memory device according to some other embodiments.

FIG. 8 is an enlarged view illustrating a region P3 of FIG. 7.

FIG. 9 is an exemplary cross-sectional view illustrating a semiconductor memory device according to some other embodiments.

FIG. 10 is an enlarged view illustrating a region P4 of FIG. 9.

FIG. 11 is an enlarged view illustrating a region P5 of FIG. 9.

FIGS. 12 and 13 are exemplary cross-sectional views illustrating a semiconductor memory device according to some other embodiments.

FIG. 14 is an exemplary cross-sectional view illustrating a semiconductor memory device according to some other embodiments.

FIG. 15 is an enlarged view illustrating a region Q2 of FIG. 14.

FIG. 16 is an exemplary cross-sectional view illustrating a semiconductor memory device according to some other embodiments.

FIGS. 17 to 25 are views of stages in a method for manufacturing a semiconductor memory device according to some embodiments.

FIG. 26 is an exemplary block diagram illustrating an electronic system according to some embodiments.

FIG. 27 is an exemplary perspective view illustrating an electronic system according to some embodiments.

FIG. 28 is a schematic cross-sectional view taken along line I-I of FIG. 27.

### DETAILED DESCRIPTION

It will be understood that, although the terms “first”, “second”, “upper portion”, “lower portion”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. Also, a lower element or component discussed below could be termed an upper element or component without departing from the technical spirits of the present disclosure. As used herein, the terms “first,” “second,” and the like are merely for identification and differentiation, and are not intended to imply or require sequential inclusion (e.g., a third element and a fourth element may be described without implying or requiring the presence of a first element or second element).

Hereinafter, embodiments of the present disclosure will be described with reference to the accompanying drawings.

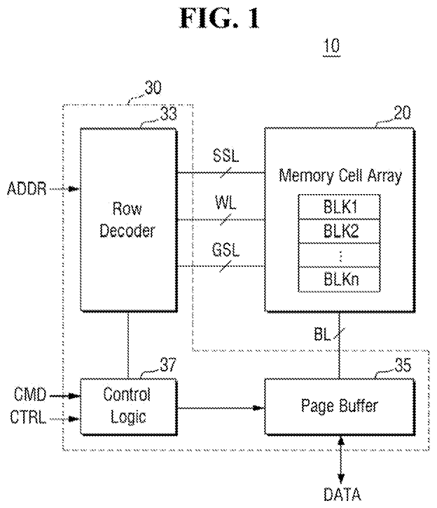

FIG. 1 is an exemplary block diagram illustrating a semiconductor memory device according to some embodiments.

Referring to FIG. 1, a semiconductor memory device 10 may include a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL and at least one ground selection line GSL. In an implementation, the memory cell blocks BLK1 to BLKn may be connected to a row decoder 33 through the word line WL, the string selection line SSL and the ground selection line GSL. In an implementation, the memory cell blocks BLK1 to BLKn may be connected to a page buffer 35 through the bit line BL.

The peripheral circuit 30 may receive an address ADDR, a command CMD and a control signal CTRL from the outside of the semiconductor memory device 10, and may transmit and receive data to and from an external device of the semiconductor memory device 10. The peripheral circuit 30 may include a control logic 37, the row decoder 33 and the page buffer 35. In an implementation, the peripheral circuit 30 may further include various sub-circuits such as an input/output circuit, a voltage generating circuit for generating various voltages required for the operation of the semiconductor memory device 10 and an error correction circuit for correcting an error of data DATA read from the memory cell array 20.

The control logic 37 may be connected to the row decoder 33, the input/output circuit and the voltage generating circuit. The control logic 37 may control the overall operation of the semiconductor memory device 10. The control logic 37 may generate various internal control signals used in the semiconductor memory device 10 in response to the control signal CTRL. In an implementation, the control logic 37 may adjust a voltage level provided to the word line WL and the bit line BL when a memory operation such as a program operation or an erase operation is performed.

The row decoder 33 may select at least one of the plurality of memory cell blocks BLK1 to BLKn in response to the address ADDR, and may select at least one word line WL, at least one string selection line SSL and at least one ground selection line GSL of the selected memory cell blocks BLK1 to BLKn. The row decoder 33 may transfer a voltage for performing a memory operation to the word line WL of the selected memory cell blocks BLK1 to BLKn.

The page buffer 35 may be connected to the memory cell array 20 through the bit line BL. The page buffer 35 may operate as a write driver or a sense amplifier. In detail, when a program operation is performed, the page buffer 35 may operate as a write driver to apply a voltage according to the data DATA to be stored in the memory cell array 20, to the bit line BL. Meanwhile, when a read operation is performed, the page buffer 35 may operate as a sense amplifier to sense the data DATA stored in the memory cell array 20.

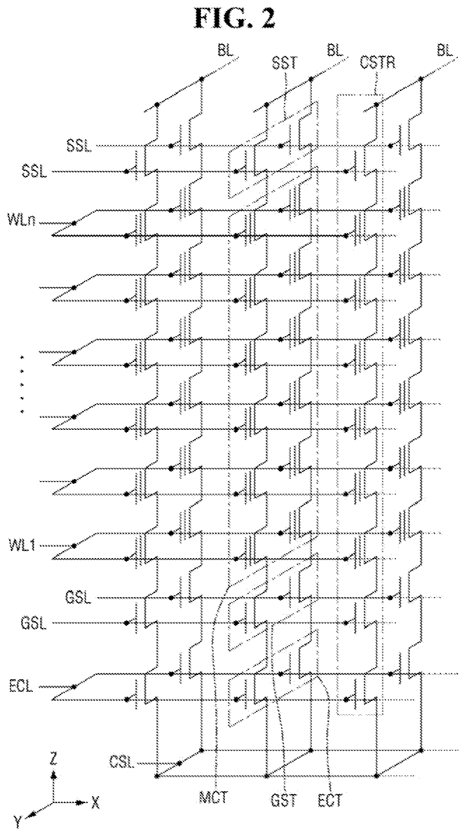

FIG. 2 is an exemplary circuit view illustrating a semiconductor memory device according to some embodiments.

Referring to FIG. 2, a memory cell array (e.g., 20 in FIG. 1) of a semiconductor memory device according to some embodiments includes a common source line CSL, a plurality of bit lines BL and a plurality of cell strings CSTR.

The common source line CSL may be extended in a first direction X. In an implementation, a plurality of common source lines CSL may be arranged two-dimensionally. In an implementation, the plurality of common source lines CSL may be spaced apart from each other and extended in the first direction X. Voltages that are electrically the same may be applied to the common source lines CSL, or different voltages may be applied to the common source lines CSL so that the common source lines CSL may be separately controlled.

The plurality of bit lines BL may be arranged two-dimensionally. In an implementation, the bit lines BL may be spaced apart from each other and extended in a second direction Y intersecting the first direction X. The plurality of cell strings CSTR may be connected to the respective bit lines BL in parallel. The cell strings CSTR may be commonly connected to the common source line CSL. That is, the plurality of cell strings CSTR may be disposed between the bit lines BL and the common source line CSL.

Each of the cell strings CSTR may include a ground selection transistor GST connected to the common source line CSL, a string selection transistor SST connected to the bit line BL and a plurality of memory cell transistors MCT disposed between the ground selection transistor GST and the string selection transistor SST. Each of the memory cell transistors MCT may include a data storage element. The ground selection transistor GST, the string selection transistor SST and the memory cell transistors MCT may be connected in series in a third direction Z. In the present disclosure, the first direction X, the second direction Y and the third direction Z may be substantially perpendicular to one another.

The common source line CSL may be commonly connected to sources of the ground selection transistors GST. In an implementation, the ground selection line GSL, a plurality of word lines WL1 to WLn and the string selection line SSL may be disposed between the common source line CSL and the bit line BL. The ground selection line GSL may be used as a gate electrode of the ground selection transistor GST, the word lines WL1 to WLn may be used as gate electrodes of the memory cell transistors MCT, and the string selection line SSL may be used as a gate electrode of the string selection transistor SST.

In an implementation, an erase control transistor ECT may be between the common source line CSL and the ground selection transistor GST. The common source line CSL may be commonly connected to sources of the erase control transistors ECT. An erase control line ECL may be between the common source line CSL and the ground selection line GSL. The erase control line ECL may be used as a gate electrode of the erase control transistor ECT. The erase control transistors ECT may generate a gate induced drain leakage (GIDL) to perform an erase operation of the memory cell array.

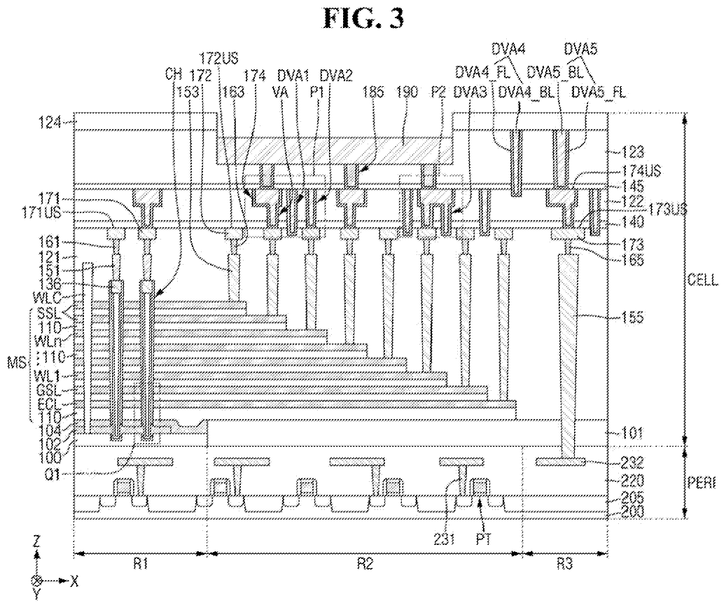

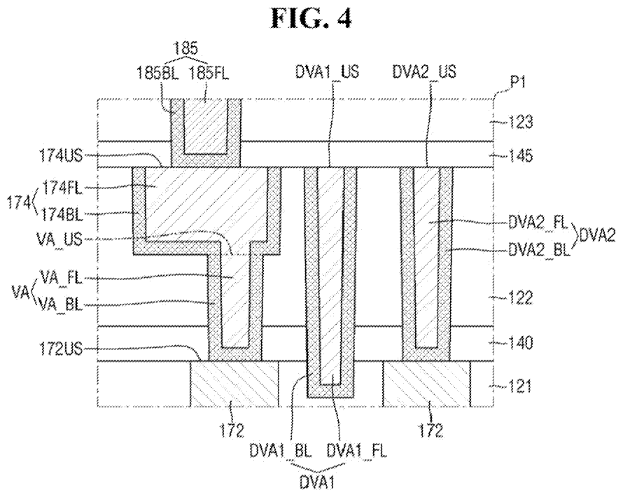

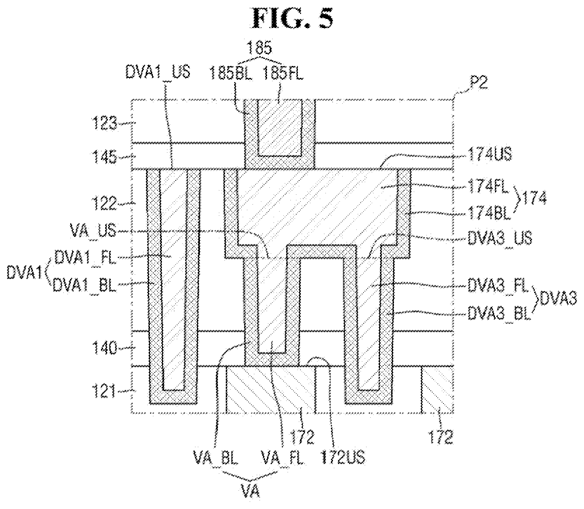

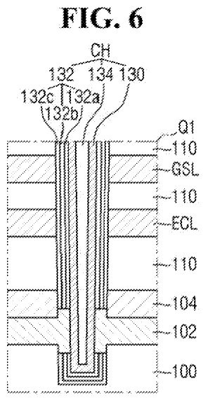

FIG. 3 is an exemplary cross-sectional view illustrating a semiconductor memory device according to some embodiments. FIG. 4 is an enlarged view illustrating a region P1 of FIG. 3. FIG. 5 is an enlarged view illustrating a region P2 of FIG. 3. FIG. 6 is an enlarged view illustrating a region Q1 of FIG. 3.

Referring to FIGS. 3 to 6, the semiconductor memory device according to some embodiments includes a cell structure CELL and a peripheral structure PERI.

In an implementation, the cell structure CELL may include a cell substrate 100, a mold structure MS, a first interlayer insulating layer 121, a second interlayer insulating layer 122, a third interlayer insulating layer 123, a channel structure CH, a word line cutting structure WLC, a plurality of first metal patterns 171, a plurality of second metal patterns 172, a third metal pattern 173, a plurality of fourth metal patterns 174, a plurality of cell contacts 153, a through contact 155, a first blocking layer 140, a second blocking layer 145, and first to fifth dummy vias DVA1, DVA2, DVA3, DVA4 and DVA5.

The semiconductor memory device according to some embodiments may include a cell array region R1, an extension region R2, and a pad region R3. In an implementation, as illustrated in the drawings, the cell array region R1, the extension region R2 and the pad region R3 may be connected to one another.

A memory cell array (e.g., 20 in FIG. 1), which includes a plurality of memory cells, may be on the cell array region R1. In an implementation, the channel structure CH, which will be described later, the plurality of first metal patterns 171 and the gate electrodes ECL, GSL, WL1 to WLn and SSL may be on the cell array region R1.

The extension region R2 may be disposed near the cell array region R1. The gate electrodes ECL, GSL, WL1˜WLn and SSL, which will be described below, may be stacked in the extension region R2 in a stair shape. Also, a plurality of cell contacts 153, which will be described later, may be on the extension region R2.

The pad region R3 may be inside the cell array region R1 and the extension region R2, or may be outside the cell array region R1 and the extension region R2. A through contact 155, which will be described below, may be on the pad region R3.

The substrate may include the cell array region R1, the extension region R2, and the pad region R3. In an implementation, the substrate may include a cell substrate 100 and an insulating substrate 101.

The cell substrate 100 may include, e.g., a semiconductor substrate such as a silicon substrate, a germanium substrate, or a silicon-germanium substrate. In an implementation, the cell substrate 100 may include a silicon-on-insulator (SOI) substrate or a germanium-on-insulator (GOI) substrate. In an implementation, the cell substrate 100 may include impurities. For example, the cell substrate 100 may include n-type impurities (e.g., phosphorus (P), arsenic (As), or the like). As used herein, the term “or” is not an exclusive term, e.g., “A or B” would include A, B, or A and B.

The insulating substrate 101 may be in the extension region R2 and the pad region R3. In an implementation, the insulating substrate 101 may include, e.g., silicon oxide, silicon nitride, silicon oxynitride, or silicon carbide. In an implementation, the insulating substrate 101 may be in the cell substrate 100.

The mold structure MS may be on a front surface (e.g., upper surface) of the cell substrate 100. The mold structure MS may include a plurality of gate electrodes ECL, GSL, WL1 to WLn and SSL and a plurality of mold insulating layers 110, which are alternately stacked on the cell substrate 100. Each of the gate electrodes ECL, GSL, WL1 to WLn and SSL and each of the mold insulating layers 110 may have a layered structure in which they are extended in parallel with the upper surface of the cell substrate 100. The gate electrodes ECL, GSL, WL1 to WLn and SSL may be sequentially stacked on the cell substrate 100 by being spaced apart from one another by the mold insulating layers 110.

The gate electrodes ECL, GSL, WL1 to WLn and SSL may be stacked in the extension region R2 in a stair shape. For example, the gate electrodes ECL, GSL, WL1 to WLn and SSL may be extended at their respective lengths different from one another in the first direction X to have a step difference. In an implementation, the gate electrodes ECL, GSL, WL1 to WLn and SSL may have a step difference in the second direction Y. Therefore, each of the gate electrodes ECL, GSL, WL1 to WLn and SSL may be exposed from other gate electrodes. The exposed region may refer to a region in which each of the cell contacts 153 is in contact with the gate electrodes.

In an implementation, the gate electrodes ECL, GSL, WL1 to WLn and SSL may include an erase control line ECL, a ground selection line GSL and a plurality of word lines WL1 to WLn, which are sequentially stacked on the cell substrate 100. In an implementation, the erase control line ECL may be omitted.

The mold insulating layers 110 may be stacked on the extension region R2 in a stair shape. In an implementation, the mold insulating layers 110 may extend at their respective lengths different from each other in the first direction X to have a step difference. In an implementation, the mold insulating layers 110 may have a step difference in the second direction Y.

Each of the gate electrodes ECL, GSL, WL1 to WLn and SSL may include a conductive material, e.g., metal such as tungsten (W), cobalt (Co) or nickel (Ni), or a semiconductor material such as silicon. In an implementation, each of the gate electrodes ECL, GSL, WL1 to WLn and SSL may include tungsten (W). In an implementation, the gate electrodes ECL, GSL, WL1 to WLn and SSL may be multiple layers. In an implementation, when the gate electrodes ECL, GSL, WL1 to WLn and SSL are multiple layers, the gate electrodes ECL, GSL, WL1 to WLn and SSL may include a gate electrode barrier layer and a gate electrode filling layer. The gate electrode barrier layer may include, e.g., titanium nitride (TiN), and the gate electrode filling layer may include, e.g., tungsten (W).

The mold insulating layer 110 may include an insulating material, e.g., silicon oxide, silicon nitride, or silicon oxynitride. In an implementation, the mold insulating layer 110 may include silicon oxide.

The channel structure CH may be in the mold structure MS on the cell array region R1. The channel structure CH may extend (e.g., lengthwise) in a vertical direction (hereinafter, referred to as third direction Z) intersecting the upper surface of the cell substrate 100 to pass through the mold structure MS. In an implementation, the channel structure CH may have a pillar shape (e.g., cylindrical shape) extending in the third direction Z. In an implementation, the channel structure CH may intersect each of the gate electrodes ECL, GSL, WL1 to WLn and SSL.

The channel structure CH may include a semiconductor pattern 130 and an information storage layer 132.

The semiconductor pattern 130 may extend in the third direction Z and pass through the mold structure MS. In an implementation, as illustrated in the drawings, the semiconductor pattern 130 may have a cup shape. In an implementation, the semiconductor pattern 130 may have various shapes such as a cylindrical shape, a quadrangular barrel shape, or a filled pillar shape. The semiconductor pattern 130 may include, e.g., a semiconductor material such as monocrystalline silicon, polycrystalline silicon, an organic semiconductor material, or a carbon nanostructure.

The information storage layer 132 may be between the semiconductor pattern 130 and each of the gate electrodes ECL, GSL, WL1 to WLn and SSL. In an implementation, the information storage layer 132 may extend along an outer side of the semiconductor pattern 130. The information storage layer 132 may include, e.g., silicon oxide, silicon nitride, silicon oxynitride, or a high dielectric constant material (high-k material) having a dielectric constant higher than that of silicon oxide. The high-k material may include, e.g., aluminum oxide, hafnium oxide, lanthanum oxide, tantalum oxide, titanium oxide, lanthanum hafnium oxide, lanthanum aluminum oxide, dysprosium scandium oxide, or their combination.

In an implementation, the information storage layer 132 may be a multi-layer. In an implementation, as shown in FIG. 6, the information storage layer 132 may include a tunnel insulating layer 132a, a charge storage layer 132b and a blocking insulating layer 132c, which are sequentially stacked on the outer side of the semiconductor pattern 130.

The tunnel insulating layer 132a may include, e.g., silicon oxide or a high-k material (e.g., aluminum oxide (Al₂O₃) or hafnium oxide (HfO₂)) having a dielectric constant higher than that of silicon oxide. The charge storage layer 132b may include, e.g., silicon nitride. The blocking insulating layer 132c may include, e.g., silicon oxide or a high-k material (e.g., aluminum oxide (Al₂O₃) or hafnium oxide (HfO₂)) having a dielectric constant higher than that of silicon oxide.

In an implementation, the channel structure CH may further include a filling pattern 134. The filling pattern 134 may fill the inside of the semiconductor pattern 130 having a cup shape. The filling pattern 134 may include an insulating material, e.g., silicon oxide.

In an implementation, the channel structure CH may further include a channel pad 136. The channel pad 136 may be connected to the semiconductor pattern 130. In an implementation, the channel pad 136 may be inside the first interlayer insulating layer 121, which will be described below, and then may be connected to an upper portion of the semiconductor pattern 130. The channel pad 136 may include, e.g., polysilicon doped with impurities.

In an implementation, a source layer 102 and a source support layer 104 may be sequentially on the cell substrate 100. The source layer 102 and the source support layer 104 may be between the cell substrate 100 and the mold structure MS. In an implementation, the source layer 102 and the source support layer 104 may extend along the upper surface of the cell substrate 100.

In an implementation, the source layer 102 may be connected to the semiconductor pattern 130 of the channel structure CH. In an implementation, as shown in FIG. 6, the source layer 102 may be in contact (e.g., direct contact) with the semiconductor pattern 130 by passing through the information storage layer 132. The source layer 102 may be a common source line (e.g., CSL in FIG. 2) of the semiconductor memory device. The source layer 102 may include, e.g., polysilicon doped with impurities or metal.

In an implementation, the channel structure CH may pass through the source layer 102 and the source support layer 104. In an implementation, a lower portion of the channel structure CH may be buried in the cell substrate 100 by passing through the source layer 102 and the source support layer 104.

In an implementation, the source support layer 104 may be a support layer to help prevent collapse or falling of the mold stack in a replacement process for forming the source layer 102.

In an implementation, a base insulating layer may be between the cell substrate 100 and the source layer 102. The base insulating layer may include, e.g., silicon oxide, silicon nitride, or silicon oxynitride.

In an implementation, the insulating substrate 101 may be in the extension region R2 and the pad region R3. In an implementation, as illustrated in the drawings, an upper surface of the insulating substrate 101 may only be on an upper surface and a coplanar surface of the source support layer 104. In an implementation, the upper surface of the insulating substrate 101 may be higher than that of the source support layer 104.

The word line cutting structure WLC may cut the mold structure MS. The mold structure MS may be cut by the word line cutting structure WLC to form a plurality of memory cell blocks (e.g., BLK1 to BLKn in FIG. 1). In an implementation, two adjacent word line cutting structures WLC may define one memory cell block therebetween. A plurality of channel structures CH may be in each of the memory cell blocks defined by the word line cutting structure WLC.

In an implementation, the word line cutting structure WLC may cut the source layer 102 and the source support layer 104. In an implementation, as illustrated in the drawings, a lower surface of the word line cutting structure WLC may only be on a lower surface and a coplanar surface of the source layer 102. In an implementation, the lower surface of the word line cutting structure WLC may be lower than that of the source layer 102.

In an implementation, the word line cutting structure WLC may include an insulating material. In an implementation, the insulating material may fill the word line cutting structure WLC. The insulating material may include, e.g., silicon oxide, silicon nitride, or silicon oxynitride.

In an implementation, a string isolation structure may be in the mold structure MS. The string isolation structure may cut the string selection line SSL. Each of the memory cell blocks defined by the word line cutting structure WLC may be divided by the string isolation structure to form a plurality of string regions. In an implementation, the string isolation structure may define two string regions in one memory cell block.

The first interlayer insulating layer 121 may be on the mold structure MS. The first interlayer insulating layer 121 may cover the plurality of channel structures CH, the plurality of cell contacts 153 and the through contact 155. The first interlayer insulating layer 121 may include an oxide insulating material. The first interlayer insulating layer 121 may include, e.g., silicon oxide, silicon oxynitride, or a low-k material having a dielectric constant lower than that of silicon oxide.

The plurality of first metal patterns 171 may be on a substrate of the cell array region R1. The plurality of first metal patterns 171 may be on the mold structure MS. The plurality of first metal patterns 171 may be bit lines (BL in FIG. 2) of the semiconductor memory device. The plurality of first metal patterns 171 may be in the first interlayer insulating layer 121. The plurality of first metal patterns 171 may extend in the second direction Y.

In an implementation, the plurality of first metal patterns 171 may be connected to the plurality of channel structures CH. In an implementation, first and second bit line contacts 151 and 161 connected to the upper portion of each of the channel structures CH may be formed in the first interlayer insulating layer 121. The first bit line contact 151 may be on the channel structure CH. The first bit line contact 151 may be connected to the channel pad 136. The second bit line contact 161 may be on the first bit line contact 151. The second bit line contact 161 may be connected to the plurality of first metal patterns 171. The second bit line contact 161 may be between each of the first metal patterns 171 and the first bit line contact 151. The plurality of first metal patterns 171 may be electrically connected to the channel structures CH through the first and second bit line contacts 151 and 161.

The plurality of first metal patterns 171 may include a conductive material. In an implementation, the plurality of first metal patterns 171 may include tungsten (W) or copper (Cu).

The plurality of cell contacts 153 may be on the substrate of the extension region R2. The plurality of cell contacts 153 may extend in the third direction Z in the extension region R2 to pass through the first interlayer insulating layer 121. Each of the plurality of cell contacts 153 may be connected to one of the plurality of gate electrodes. In an implementation, each of the plurality of cell contacts 153 may be landed on a gate electrode, which is at the highest level, among the plurality of gate electrodes. In an implementation, each of the plurality of cell contacts 153 may be electrically connected to the gate electrode, which is at the highest level, among the plurality of gate electrodes.

An upper surface of each of the plurality of cell contacts 153 may be on a coplanar surface. A bottom surface of each of the plurality of cell contacts 153 may be on a coplanar surface.

The plurality of second metal patterns 172 may be on the extension region R2 of the substrate. The plurality of second metal patterns 172 may be on the mold structure MS. An upper surface 172US of the plurality of second metal patterns 172 may be coplanar with an upper surface 171US of the plurality of first metal patterns 171. The upper surface 172US of the plurality of second metal patterns 172 may be coplanar with an upper surface of the first interlayer insulating layer 121. In an implementation, the plurality of second metal patterns 172 may be connected to the plurality of cell contacts 153, respectively. In an implementation, a first via contact 163 may be between the plurality of second metal patterns 172 and each of the cell contacts 153. The plurality of second metal patterns 172 may be electrically connected to the respective cell contacts 153 through the first via contact 163.

The plurality of second metal patterns 172 may include a conductive material. In an implementation, the plurality of second metal patterns 172 may include tungsten (W) or copper (Cu).

The through contact 155 may be on the pad region R3 of the substrate. The through contact 155 may extend in the third direction Z on the pad region R3 to pass through the first interlayer insulating layer 121. In an implementation, the through contact 155 may pass through the insulating substrate 101. The through contact 155 may be connected to the peripheral circuit element PT of the peripheral circuit structure PERI, which will be described below, by passing through the insulating substrate 101. In an implementation, the through contact 155 may be connected to a wiring structure 232.

The third metal pattern 173 may be on the pad region R3 of the substrate. The third metal pattern 173 may be in the first interlayer insulating layer 121. An upper surface 173US of the third metal pattern 173 may be coplanar with the upper surface 171US of the plurality of first metal patterns 171 and the upper surface 172US of the plurality of second metal patterns 172. The upper surface 173US of the third metal pattern 173 may be coplanar with the upper surface of the first interlayer insulating layer 121. In an implementation, the third metal pattern 173 may be connected to the through contact 155. In an implementation, a second via contact 165 may be formed between the third metal pattern 173 and the through contact 155. The third metal pattern 173 and the through contact 155 may be electrically connected to each other through the second via contact 165.

The third metal pattern 173 may include a conductive material. In an implementation, the third metal pattern 173 may include tungsten (W) or copper (Cu).

The first blocking layer 140 may be extended along the upper surface 171US of the plurality of first metal patterns 171, the upper surface 172US of the plurality of second metal patterns 172, the upper surface 173US of the third metal pattern 173 and the upper surface of the first interlayer insulating layer 121. The first blocking layer 140 may cover the upper surface 171US of the plurality of first metal patterns 171, the upper surface 172US of the plurality of second metal patterns 172, the upper surface 173US of the third metal pattern 173 and the upper surface of the first interlayer insulating layer 121. The first blocking layer 140 may include a nitride insulating material. In an implementation, the first blocking layer 140 may be, e.g., a silicon nitride layer.

In an implementation, the second interlayer insulating layer 122 may be on the first blocking layer 140. The second interlayer insulating layer 122 may be on the plurality of first metal patterns 171, the plurality of second metal patterns 172, and the third metal pattern 173. The second interlayer insulating layer 122 may include an oxide insulating material. The second interlayer insulating layer 122 may include, e.g., silicon oxide, silicon oxynitride, or a low-k material having a dielectric constant lower than that of silicon oxide. In an implementation, a concentration of hydrogen in the second interlayer insulating layer 122 may be higher than that of hydrogen in the first interlayer insulating layer 121.

In an implementation, the plurality of fourth metal patterns 174, the plurality of vias VA, the plurality of first dummy vias DVA1, the second dummy via DVA2, and the third dummy via DVA3 may be in the second interlayer insulating layer 122.

The plurality of fourth metal patterns 174 may be connected to the plurality of first metal patterns 171, the plurality of second metal patterns 172, and the third metal pattern 173. In an implementation, the plurality of vias VA may be below the fourth metal patterns 174, respectively. The plurality of fourth metal patterns 174 may be connected to the plurality of first metal patterns 171, the plurality of second metal patterns 172, and the third metal pattern 173 through the plurality of vias VA. In an implementation, the plurality of fourth metal patterns 174 may be connected to a pad pattern 190 that will be described below.

In an implementation, each of the plurality of fourth metal patterns 174 may be a multi-layer. In an implementation, each of the plurality of fourth metal patterns 174 may include a barrier layer 174BL and a filling layer 174FL. The barrier layer 174BL of the plurality of fourth metal patterns 174 may be disposed along sidewalls and a portion of a bottom surface of the filling layer 174FL of the plurality of fourth metal patterns 174. The barrier layer 174BL of the plurality of fourth metal patterns 174 may not extend along an upper surface VA_US of the via VA.

The barrier layer 174BL of the plurality of fourth metal patterns 174 may include, e.g., a metal (e.g., non-compounded metal), a metal nitride, a metal carbonitride, or a two-dimensional (2D) material. In an implementation, the two-dimensional material may be a metallic material or a semiconducting material. The two-dimensional (2D) material may include a two-dimensional allotrope or a two-dimensional compound. In an implementation, the barrier layer 174BL of the plurality of fourth metal patterns 174 may include titanium nitride (TiN). The filling layer 174FL of the plurality of fourth metal patterns 174 may include metal such as tungsten (W), cobalt (Co), nickel (Ni) and copper (Cu). In an implementation, the filling layer 174FL of the plurality of fourth metal patterns 174 may include copper (Cu).

Each of the plurality of vias VA may be below the plurality of fourth metal patterns 174. Each of the plurality of vias VA may be between the plurality of fourth metal patterns 174 and the plurality of first metal patterns 171, between the plurality of fourth metal patterns 174 and the plurality of second metal patterns 172, or between the plurality of fourth metal patterns 174 and the third metal pattern 173.

In an implementation, each of the plurality of vias VA may be a multi-layer. In an implementation, each of the plurality of vias VA may include a barrier layer VA_BL and a filling layer VA_FL. The barrier layer VA_BL of the plurality of vias VA may be disposed along sidewalls and a bottom surface of the filling layer VA_FL of the plurality of vias VA. The filling layer VA_FL of the plurality of vias VA may be on the barrier layer VA_BL of the plurality of vias VA.

The barrier layer VA_BL of the plurality of vias VA may include, e.g., a metal, a metal nitride, a metal carbonitride, or a two-dimensional (2D) material. In an implementation, the two-dimensional material may be a metallic material or a semiconducting material. The two-dimensional (2D) material may include a two-dimensional allotrope or a two-dimensional compound. In an implementation, the barrier layer VA_BL of the plurality of vias VA may include titanium nitride (TiN). The filling layer VA_FL of the plurality of vias VA may include metal such as tungsten (W), cobalt (Co), nickel (Ni) and copper (Cu). In an implementation, the filling layer VA_FL of the plurality of vias VA may include copper (Cu).

In an implementation, the first to third dummy vias DVA1, DVA2 and DVA3 may pass through the first blocking layer 140.

In an implementation, the plurality of first dummy vias DVA1 may be on the pad region R3 and the extension region R2 of the substrate. The plurality of first dummy vias DVA1 may be between the plurality of second metal patterns 172 or between the second metal pattern 172 and the third metal pattern 173. In an implementation, as illustrated in FIG. 4, at least a portion of the first dummy via DVA1 may be in the first interlayer insulating layer 121. In an implementation, at least a portion of the first dummy via DVA1 may overlap the plurality of second metal patterns 172 in the first direction X. A level of a bottom surface of the plurality of first dummy vias DVA1 may be different from that of a bottom surface of the first blocking layer 140. This may be due to an etch selectivity of the second metal pattern 172 and the first interlayer insulating layer 121. In an implementation, at least a portion of the first dummy via DVA1 may be in the second interlayer insulating layer 122.

In an implementation, an upper surface DVA1_US of the plurality of first dummy vias DVA1 may be coplanar with the upper surface 174US of the plurality of fourth metal patterns 174. The upper surface DVA1_US of the plurality of first dummy vias DVA1 may be coplanar with an upper surface of the second interlayer insulating layer 122. In an implementation, the upper surface DAV1_US of the first dummy vias DVA1 may be in contact with the second blocking layer 145 that will be described below.

In an implementation, each of the plurality of first dummy vias DVA1 may be a multi-layer. In an implementation, each of the plurality of first dummy vias DVA1 may include a barrier layer DVA1_BL and a filling layer DVA1_FL. The barrier layer DVA1_BL of the plurality of first dummy vias DVA1 may be disposed along sidewalls and a bottom surface of the filling layer DVA1_FL of the plurality of first dummy vias DVA1. The filling layer DVA1_FL of the plurality of first dummy vias DVA1 may be on the barrier layer DVA1_BL of the plurality of first dummy vias DVA1.

The barrier layer DVA1_BL of the plurality of first dummy vias DVA1 may include the same material as that of the barrier layer DVA_BL of the via VA, and the filling layer DVA1_FL of the plurality of first dummy vias DVA1 may be formed of the same material as that of the filling layer VA_FL of the via VA. Therefore, a detailed description of the first dummy vias DVA1 may be omitted.

In an implementation, the second dummy via DVA2 may be landed on the upper surface 172US of the second metal pattern 172. The second dummy via DVA2 may not be in the first interlayer insulating layer 121. An upper surface DVA2_US of the second dummy via DVA2 may be coplanar with the upper surface 174US of the fourth metal pattern 174. The upper surface DVA2_US of the second dummy via DVA2 may be coplanar with an upper surface of the second interlayer insulating layer 122. In an implementation, the upper surface DVA2_US of the second dummy via DAV2 may be in contact with the second blocking layer 145 that will be described later.

In an implementation, the second dummy via DVA2 may be a multi-layer. In an implementation, the second dummy via DVA2 may include a barrier layer DVA2_BL and a filling layer DVA2_FL. The barrier layer DVA2_BL of the second dummy via DVA2 may be disposed along sidewalls and a bottom surface of the filling layer DVA2_FL of the second dummy vias DVA2. The filling layer DVA2_FL of the second dummy via DVA2 may be on the barrier layer DVA2_BL of the second dummy via DVA2.

The barrier layer DVA2_BL of the second dummy via DVA2 may include the same material as that of the barrier layer VA_BL of the via VA, and the filling layer DVA2_FL of the second dummy via DVA2 may be formed of the same material as that of the filling layer VA_FL of the via VA. Therefore, a detailed description the second dummy via DVA2 may be omitted.

In an implementation, the third dummy via DVA3 may be below the fourth metal pattern 174. In an implementation, as illustrated in FIG. 5, the third dummy via DVA3 may be connected to a portion of the plurality of fourth metal patterns 174. At least a portion of the third dummy via DVA3 may be in the first interlayer insulating layer 121. At least a portion of the third dummy via DVA3 may overlap the plurality of second metal patterns 172 in the first direction X. A level of a bottom surface of the third dummy via DVA3 may be lower than that of the bottom surface of the first blocking layer 140, e.g., the bottom surface of the third dummy via DVA3 may be closer to the substrate than the bottom surface of the first blocking layer 140).

In an implementation, the bottom surface of the third dummy via DVA3 may be coplanar with that of the first dummy via DVA1. This may be because that the first dummy via DVA1 and the third dummy via DVA3 may be formed by the same process. An upper surface DVA3_US of the third dummy via DVA3 may be coplanar with the upper surface VA_US of the via VA.

In an implementation, the third dummy via DVA3 may be a multi-layer. In an implementation, the third dummy via DVA3 may include a barrier layer DVA3_BL and a filling layer DVA3_FL. The barrier layer DVA3_BL of the third dummy via DVA3 may be disposed along sidewalls and a bottom surface of the filling layer DVA3_FL of the third dummy vias DVA3. The filling layer DVA3_FL of the third dummy via DVA3 may be on the barrier layer DVA3_BL of the third dummy via DVA3.

The barrier layer DVA3_BL of the third dummy via DVA3 may include the same material as that of the barrier layer VA_BL of the via VA, and the filling layer DVA FL of the third dummy via DVA3 may include the same material as that of the filling layer VA_FL of the via VA. Therefore, a detailed description of the third dummy via DVA3 may be omitted.

In an implementation, the first to third dummy vias DVA1, DVA2 and DVA3 may not be used for the purpose of signal transfer. In an implementation, the first to third dummy vias DVA1, DVA2 and DVA3 may be used as a passage through which hydrogen moves. In an implementation, hydrogen in the second interlayer insulating layer 122 may be moved to the first interlayer insulating layer 121 through the first to third dummy vias DVA1, DVA2 and DVA3. Therefore, a semiconductor memory device with improved reliability may be implemented.

In an implementation, the second blocking layer 145 may be on the second interlayer insulating layer 122. The second blocking layer 145 may extend along the upper surface 174US of the plurality of fourth metal patterns 174 and the upper surface of the second interlayer insulating layer 122. The second blocking layer 145 may include a nitride insulating material. In an implementation, the second blocking layer 145 may be, e.g., a silicon nitride layer.

The third interlayer insulating layer 123 may be on the second blocking layer 145. The third interlayer insulating layer 123 may be on the plurality of fourth metal patterns 174. The third interlayer insulating layer 123 may include an oxide insulating material. The third interlayer insulating layer 123 may include, e.g., silicon oxide, silicon oxynitride, or a low-k material having a dielectric constant lower than that of silicon oxide. In an implementation, a concentration of hydrogen in the third interlayer insulating layer 123 may be higher than that of hydrogen in the second interlayer insulating layer 122.

The semiconductor memory device according to some embodiments may further include a fourth dummy via DVA4 and a fifth dummy via DVA5. The fourth dummy via DVA4 and the fifth dummy via DVA5 may pass through the second blocking layer 145.

In an implementation, the fourth dummy via DVA4 may pass through the second blocking layer 145, and at least a portion of the fourth dummy via DVA4 may be in the second interlayer insulating layer 122. Another portion of the fourth dummy via DVA4 may be in the third interlayer insulating layer 123. The fourth dummy via DVA4 may be between the plurality of fourth metal patterns 174. At least a portion of the fourth dummy via DVA4 may overlap the plurality of fourth metal patterns 174 in the first direction X.

The fifth dummy via DVA5 may pass through the second blocking layer 145, and may be landed on the upper surface 174US of the fourth metal pattern 174. The fifth dummy via DVA5 may not be in the second interlayer insulating layer 122.

In an implementation, the fourth dummy via DVA4 and the fifth dummy via DVA5 may each be a multi-layer. In an implementation, the fourth dummy via DVA4 may include a barrier layer DVA4_BL and a filling layer DVA4_FL, and the fifth dummy via DVA5 may include a barrier layer DVA5_BL and a filling layer DVA5_FL. The barrier layer DVA4_BL of the fourth dummy via DVA4 may be disposed along sidewalls and a bottom surface of the filling layer DVA4_FL of the fourth dummy via DVA4. The filling layer DVA4_FL of the fourth dummy via DVA4 may be on the barrier layer DVA4_BL of the fourth dummy via DVA4. The barrier layer DVA5_BL of the fifth dummy via DVA5 may be disposed along sidewalls and a bottom surface of the filling layer DVA5_FL of the fifth dummy via DVA5. The filling layer DVA5_FL of the fifth dummy via DVA5 may be on the barrier layer DVA5_BL of the fifth dummy via DVA5.

Each of the barrier layer DVA4_BL of the fourth dummy via DVA4 and the barrier layer DVA5_BL of the fifth dummy via DVA5 may include the same material as that of the barrier layer VA_BL of the via VA, and each of the filling layer DVA4_FL of the fourth dummy via DVA4 and the filling layer DVA5_FL of the fifth dummy via DVA5 may include the same material as that of the filling layer VA_FL of the via VA. Therefore, a detailed description of the fourth dummy via DVA4 and the fifth dummy via DVA5 may be omitted.

In an implementation, the fourth and fifth dummy vias DVA4 and DVA5 may not be used for the purpose of signal transfer. In an implementation, the fourth and fifth dummy vias DVA4 and DVA5 may be used as a passage through which hydrogen moves. In an implementation, hydrogen in the third interlayer insulating layer 123 may be moved to the second interlayer insulating layer 122 through the fourth and fifth dummy vias DVA4 and DVA5. Therefore, a semiconductor memory device with improved reliability may be implemented.

In an implementation, a pad via 185 may be in the third interlayer insulating layer 123. The pad via 185 may be connected to the plurality of fourth metal patterns 174. In an implementation, the pad via 185 may be connected to the pad pattern 190. In an implementation, the pad via 185 may be a multi-layer. In an implementation, the pad via 185 may include a barrier layer 185BL and a filling layer 185FL. The barrier layer 185BL of the pad via 185 may be disposed along sidewalls and a bottom surface of the filling layer 185FL of the pad via 185. In an implementation, the barrier layer 185BL of the pad via 185 may be between the filling layer 185FL and the third interlayer insulating layer 123 of the pad via 185.

The barrier layer 185BL of the pad via 185 may include, e.g., a metal, a metal nitride, a metal carbonitride, or a two-dimensional (2D) material. In an implementation, the two-dimensional material may include a metallic material or a semiconducting material. The two-dimensional (2D) material may include a two-dimensional allotrope or a two-dimensional compound. In an implementation, the barrier layer 185BL of the pad via 185 may include titanium nitride (TiN). In an implementation, the filling layer 185FL of the pad via 185 may include metal such as tungsten (W), cobalt (Co), nickel (Ni) and copper (Cu). In an implementation, the filling layer 185FL of the pad via 185 may include copper (Cu).

In an implementation, the semiconductor memory device of the present disclosure may further include a pad pattern 190 and a capping layer 124.

The capping layer 124 may be on the third interlayer insulating layer 123. The capping layer 124 may help protect the semiconductor memory device of the present disclosure. The capping layer 124 may include a nitride insulating material.

The pad pattern 190 may be in the third interlayer insulating layer 123. The pad pattern 190 may be connected to the pad via 185. In an implementation, an upper surface of the pad pattern 190 may be exposed. The semiconductor memory device of the present disclosure may be electrically connected to an external device through the exposed region. The pad pattern 190 may include a conductive material. In an implementation, the pad pattern 190 may include, e.g., aluminum (Al).

In an implementation, the peripheral circuit structure PERI may include a peripheral circuit board 200 and a peripheral circuit element PT.

The peripheral circuit board 200 may be below the cell substrate 100. In an implementation, an upper surface of the peripheral circuit board 200 may face a lower surface of the cell substrate 100. The peripheral circuit board 200 may include, e.g., a semiconductor substrate such as a silicon substrate, a germanium substrate, or a silicon-germanium substrate. In an implementation, the peripheral circuit board 200 may include a silicon-on-insulator (SOI) substrate or a germanium-on-insulator (GOI) substrate.

The peripheral circuit element PT may be on the peripheral circuit board 200. The peripheral circuit element PT may constitute a peripheral circuit (e.g., 30 in FIG. 1) that controls the operation of the semiconductor memory device. In an implementation, the peripheral circuit element PT may include a control logic (e.g., 37 in FIG. 1), a row decoder (e.g., 33 in FIG. 1), and a page buffer (e.g., 35 in FIG. 1). In the following description, a surface of the peripheral circuit board 200 on which the peripheral circuit element PT is disposed may be referred to as a front side of the peripheral circuit board 200. In an implementation, a surface of the peripheral circuit board 200, which is opposite to the front side of the peripheral circuit board 200, may be referred to as a back side of the peripheral circuit board 200.

The peripheral circuit element PT may include, e.g., a transistor. In an implementation, the peripheral circuit element PT may include various passive elements such as a capacitor, a resistor, or an inductor as well as various active elements such as a transistor.

In an implementation, the back side of the cell substrate 100 may face the front side of the peripheral circuit board 200. In an implementation, an inter-wiring insulating layer 220 covering the peripheral circuit element PT may be on the front side of the peripheral circuit board 200. The cell substrate 100 or the insulating substrate 101 may be stacked on an upper surface of the inter-wiring insulating layer 220.

The third metal pattern 173 may be connected to the peripheral circuit element PT through the through contact 155. In an implementation, a plurality of wiring structures 232 connected to the peripheral circuit element PT may be in the inter-wiring insulating layer 220. Each of the plurality of wiring structures 232 may be connected to the peripheral circuit element PT through a plurality of wiring contacts 231.

The through contact 155 may connect the third metal pattern 173 with the wiring structure 232 by passing through the first interlayer insulating layer 121 and the insulating substrate 101. Therefore, the bit line BL, each of the gate electrodes ECL, GSL, WL1 to WLn and SSL or the source layer 102 may be electrically connected to the peripheral circuit element PT.

The peripheral circuit elements PT may be isolated by a peripheral element isolation layer 205. In an implementation, the peripheral element isolation layer 205 may be in the peripheral circuit board 200. The peripheral element isolation layer 205 may be a shallow trench isolation (STI) layer. The peripheral element isolation layer 205 may define an active region of the peripheral circuit elements PT. The peripheral element isolation layer 205 may include an insulating material. The peripheral element isolation layer 205 may include, e.g., silicon nitride, silicon oxide, or silicon oxynitride.

Hereinafter, some other embodiments of the semiconductor memory device of the present disclosure will be described. For convenience of description, the following description will be based on differences from those described with reference to FIGS. 3 to 6.

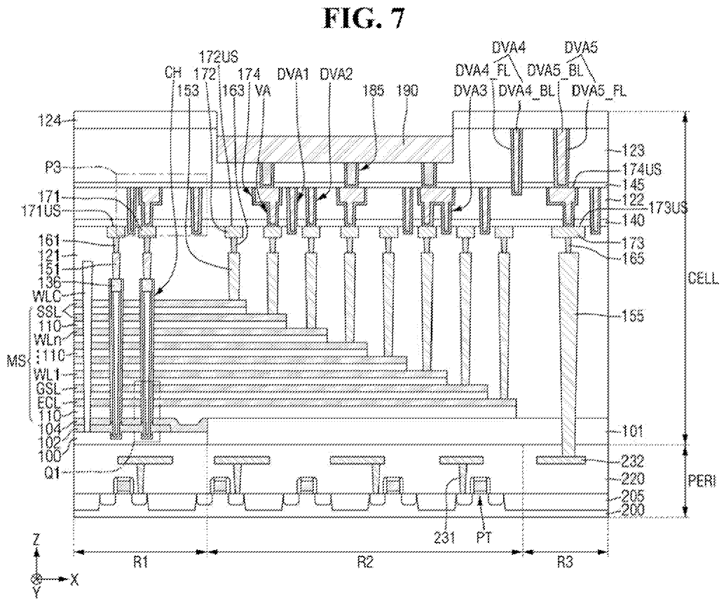

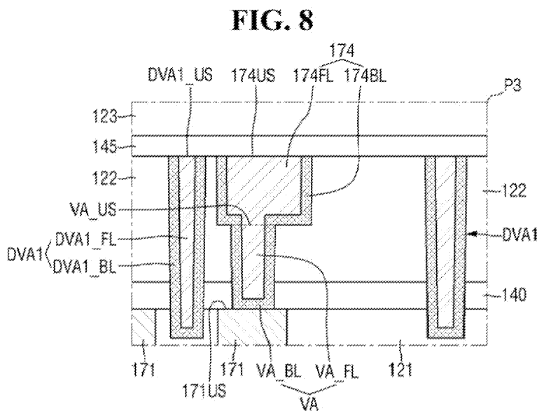

FIG. 7 is an exemplary cross-sectional view illustrating a semiconductor memory device according to some other embodiments. FIG. 8 is an enlarged view illustrating a region P3 of FIG. 7.

Referring to FIGS. 7 and 8, in a semiconductor memory device according to some embodiments, the first dummy vias DVA1 may be on the cell array region R1 of the substrate. A portion of the first dummy vias DVA1 may be between the plurality of first metal patterns 171. Another portion of the first dummy vias DVA1 may be between the first metal pattern 171 and the second metal pattern 172. Another portion of the first dummy vias DVA1 may be on the word line cutting structure WLC. Another portion of the first dummy vias DVA1 may overlap the word line cutting structure WLC in the third direction Z.

In an implementation, at least a portion of the first dummy vias DVA1 may be in the first interlayer insulating layer 121. The first dummy vias DVA1 may include a portion that overlaps the first metal pattern 171 in the first direction X.

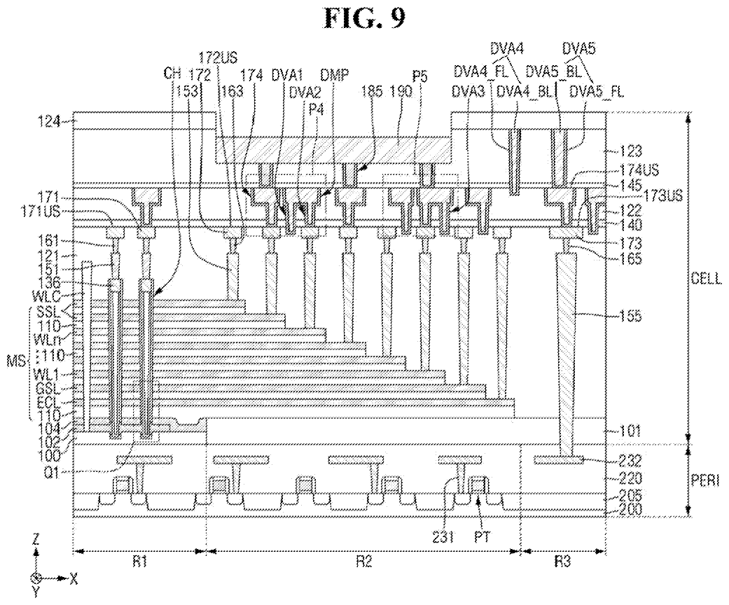

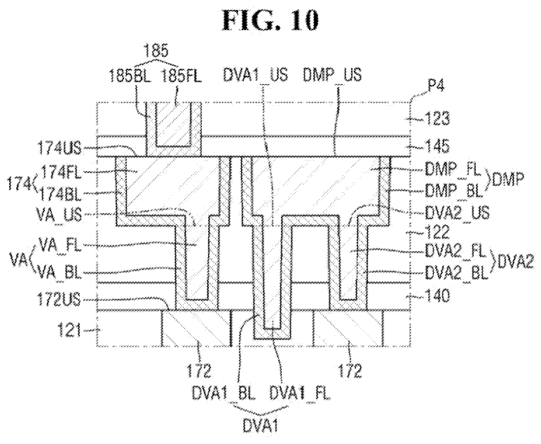

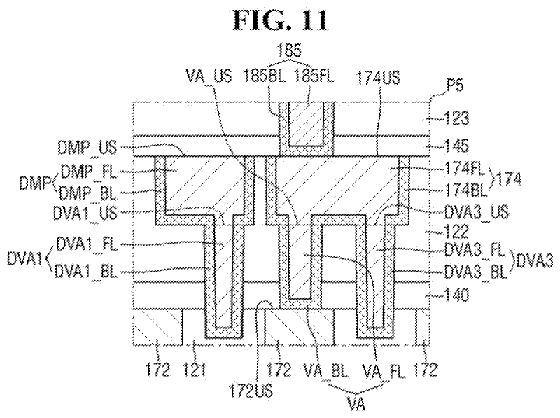

FIG. 9 is an exemplary cross-sectional view illustrating a semiconductor memory device according to some other embodiments. FIG. 10 is an enlarged view illustrating a region P4 of FIG. 9. FIG. 11 is an enlarged view illustrating a region P5 of FIG. 9.

Referring to FIGS. 9 to 11, the semiconductor memory device according to some embodiments may further include at least one dummy metal pattern DMP.

At least one dummy metal pattern DMP may be on the first dummy via DVA1 or the second dummy via DVA2. In an implementation, as illustrated in FIG. 10, the dummy metal pattern DMP may be on the first dummy via DVA1 and the second dummy via DVA2. The first dummy via DVA1 and the second dummy via DVA2 may be below one dummy metal pattern DMP. The first dummy via DVA1 and the second dummy via DVA2 may share one dummy metal pattern DMP.

In an implementation, the dummy metal pattern DMP and the fourth metal pattern 174 may be formed by the same process. Therefore, an upper surface DMP_US of the dummy metal pattern DMP may be coplanar with the upper surface 174US of the fourth metal pattern 174. Likewise, the upper surface VA_US of the via VA may be coplanar with the upper surface DVA1_US of the first dummy via DVA1. The upper surface VA_US of the via VA is coplanar with the upper surface DVA2_US of the second dummy via DVA2.

In an implementation, as illustrated in FIG. 11, the dummy metal pattern DMP may be connected to the first dummy via DVA1. The first dummy via DVA1 may be below the dummy metal pattern DMP. In this case, the first dummy via DVA1 and the second dummy via DVA2 do not share one dummy metal pattern DMP. The upper surface DVA1_US of the first dummy via DVA1 may be coplanar with the upper surface DVA3_US of the third dummy via DVA3.

The pad via 185 may not be connected to the dummy metal pattern DMP. In an implementation, the dummy metal pattern DMP may not be used for the purpose of signal transfer. The dummy metal pattern DMP may be a passage through which hydrogen moves. The hydrogen may be moved from the second interlayer insulating layer 122 to the first interlayer insulating layer 121 by using the dummy metal pattern DMP.

In an implementation, each of the dummy metal patterns DMP may be a multi-layer. In an implementation, each of the dummy metal patterns DMP may include a barrier layer DMP_BL and a filling layer DMP_FL. The barrier layer DMP_BL of the dummy metal patterns DMP may be disposed along sidewalls and a portion of the bottom surface of the filling layer DMP_FL of the dummy metal patterns DMP. The barrier layer DMP_BL of the dummy metal patterns DMP may not extend along the upper surface DVA1_US of the first dummy via DVA1 or the upper surface DVA2_US of the second dummy via DVA2.

The barrier layer DMP_BL of the dummy metal patterns DMP may include, e.g., a metal, a metal nitride, a metal carbonitride, or a two-dimensional (2D) material. In an implementation, the two-dimensional material may include a metallic material or a semiconducting material. The two-dimensional (2D) material may include a two-dimensional (2D) allotrope or a two-dimensional compound. In an implementation, the barrier layer DMP_BL of the dummy metal patterns DMP may include titanium nitride (TiN). In an implementation, the filling layer DMP_FL of the dummy metal patterns DMP may include metal such as tungsten (W), cobalt (Co), nickel (Ni) and copper (Cu). In an implementation, the filling layer DMP_FL of the dummy metal patterns DMP may include copper Cu.

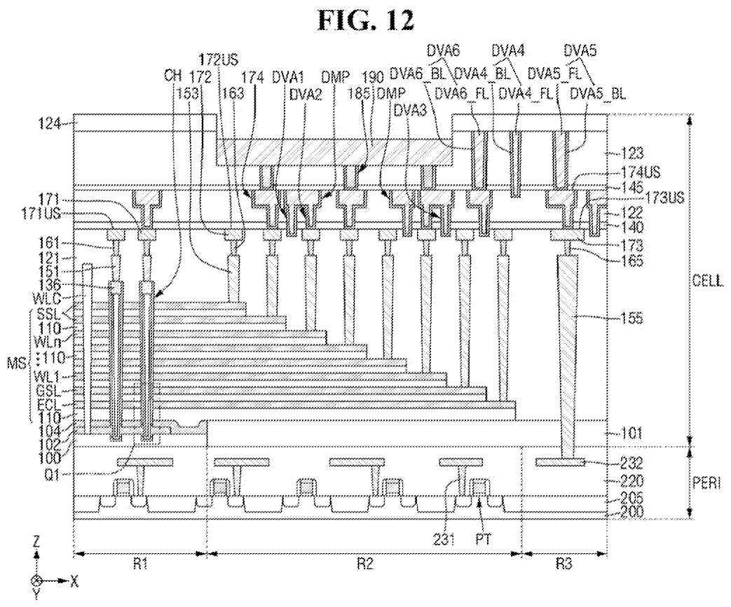

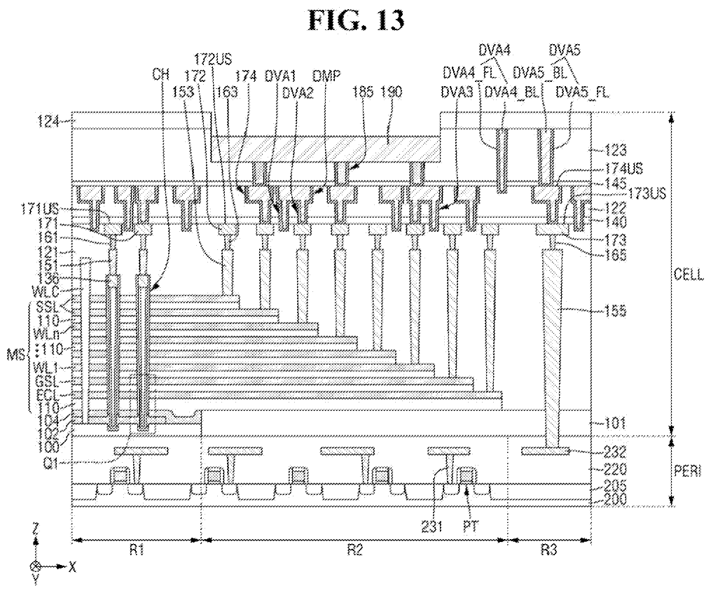

FIGS. 12 and 13 are exemplary cross-sectional views illustrating a semiconductor memory device according to some other embodiments.

First, referring to FIG. 12, the semiconductor memory device according to some embodiments may further include a sixth dummy via DVA6. The sixth dummy via DVA6 may be landed in one of the plurality of fourth metal patterns 174. The sixth dummy via DVA6 may not be used for the purpose of signal transfer. The sixth dummy via DVA6 may be a passage through which hydrogen moves. The hydrogen in the third interlayer insulating layer 123 may be moved to the second interlayer insulating layer 122 through the sixth dummy via DVA6.

In an implementation, the sixth dummy via DVA6 may be a multi-layer. In an implementation, the sixth dummy via DVA6 may include a barrier layer DVA6_BL and a filling layer DVA6_FL. The barrier layer DVA6_BL of the sixth dummy via DVA6 may be disposed along sidewalls and a bottom surface of the filling layer DVA6_FL of the sixth dummy via DVA6. The filling layer DVA6_FL of the sixth dummy via DVA6 may be on the barrier layer DVA6_BL of the sixth dummy via DVA6.

The barrier layer DVA6_BL of the sixth dummy via DVA6 may include the same material as that of the barrier layer VA_BL of the via VA, and the filling layer DVA6_FL of the sixth dummy via DVA6 may include the same material as that of the filling layer VA_FL of the via VA. Therefore, a detailed description of the sixth dummy via DVA6 may be omitted.

Referring to FIG. 13, the dummy metal pattern DMP and the first dummy via DVA1 may be on the cell array region R1 of the substrate. At least a portion of the dummy metal pattern DMP may overlap the plurality of first metal patterns 171 in the third direction Z. The first dummy via DVA1 may be between the plurality of first metal patterns 171.

Likewise, the dummy metal pattern DMP and the first dummy via DVA1 may not be used for the purpose of signal transfer. Hydrogen in the second interlayer insulating layer 122 may be moved to the first interlayer insulating layer 121 through the dummy metal pattern DMP and the first dummy via DVA1.

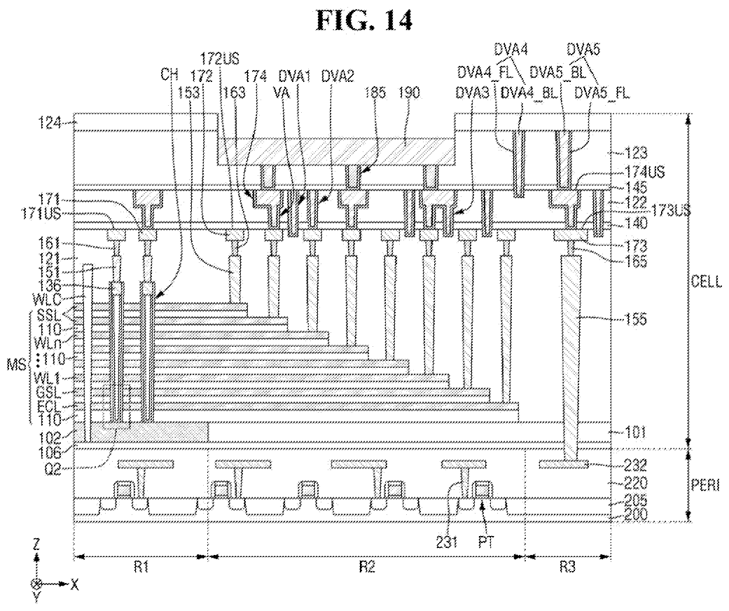

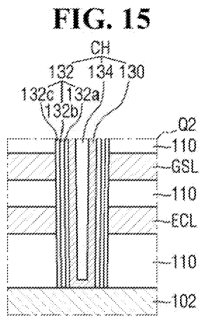

FIG. 14 is an exemplary cross-sectional view illustrating a semiconductor memory device according to some other embodiments. FIG. 15 is an enlarged view illustrating a region Q2 of FIG. 14.

Referring to FIGS. 14 and 15, in the semiconductor memory device according to some embodiments, the source layer 102 may be connected to the semiconductor pattern 130.

The source layer 102 may be in contact with the bottom surface of the information storage layer 132 and the bottom surface of the semiconductor pattern 130. The source layer 102 may not expose sidewalls of the semiconductor pattern 130. The source layer 102 may expose the bottom surface of the semiconductor pattern 130. In this case, the source support layer (104 in FIG. 3) may be omitted.

In an implementation, a metal silicide layer 106 may be below the source layer 102 and the insulating substrate 101. The metal silicide layer 106 may be between the source layer 102 and the insulating substrate 101 and the inter-wiring insulating layer 220. In an implementation, the metal silicide layer 106 may be omitted.

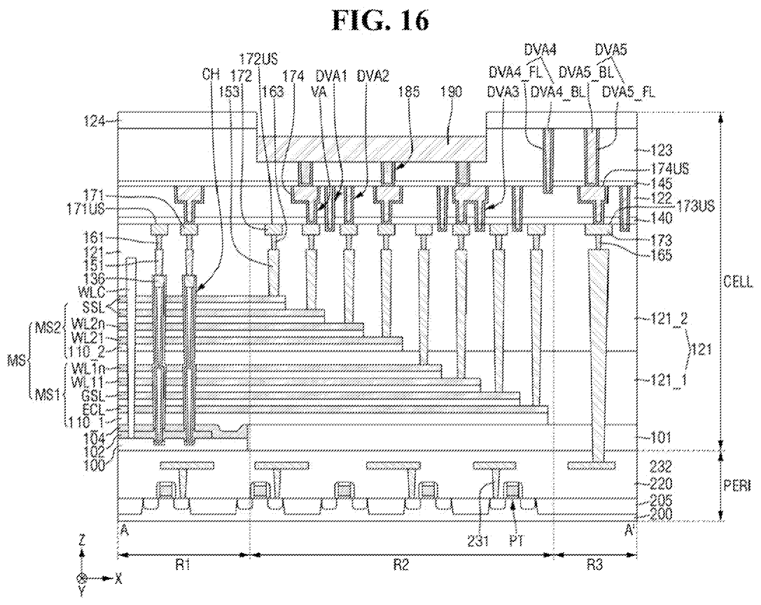

FIG. 16 is an exemplary cross-sectional view illustrating a semiconductor memory device according to some other embodiments.

Referring to FIG. 16, in the semiconductor memory device according to some embodiments, the mold structure MS may include a lower mold structure MS1 and an upper mold structure MS2.

The first interlayer insulating layer 121 may include a lower first interlayer insulating layer 121_1 and an upper first interlayer insulating layer 121_2. The mold insulating layer 110 may include a lower mold insulating layer 110_1 and an upper mold insulating layer 110_2.

In an implementation, the upper mold structure MS2 may be on the lower mold structure MS1. The lower mold structure MS1 may be configured in such a manner that lower gate electrodes ECL, GSL, and WL11 to WL In and the lower mold insulating layer 110_1 are alternately stacked. The upper mold structure MS2 may be configured in such a manner that upper gate electrodes WL21 to WL2n and SSL and the upper mold insulating layer 110_2 are alternately stacked. The channel structure CH may pass through the upper mold structure MS2 and the lower mold structure MS1 in the third direction Z.

In an implementation, the lower first interlayer insulating layer 121_1 may be between the lower gate electrode WL In and the upper mold insulating layer 110_2. The upper first interlayer insulating layer 121_2 may be between the upper gate electrode SSL and the plurality of first metal patterns 171. In an implementation, the upper first interlayer insulating layer 121_2 may be on the lower first interlayer insulating layer 121_1.

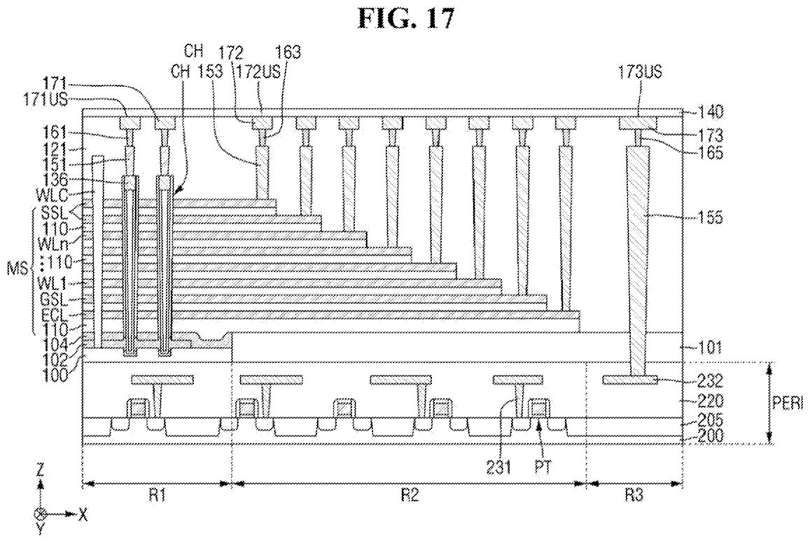

Hereinafter, a method for manufacturing a semiconductor memory device according to some embodiments of the present disclosure will be described with reference to FIGS. 17 to 25. FIGS. 17 to 25 are views of stages in a method for manufacturing a semiconductor memory device according to some embodiments.

First, referring to FIG. 17, a peripheral circuit board 200, a peripheral circuit element PT and an inter-wiring insulating layer 220 may be provided. A cell substrate 100 and an insulating substrate 101 may be formed on the inter-wiring insulating layer 220.

A mold structure MS may be formed on the cell substrate 100 and the insulating substrate 101. The mold structure MS may include a plurality of gate electrodes ECL, GSL, WL1 to WLn and SSL and a plurality of mold insulating layers 110, which are alternately stacked on the cell substrate 100. Each of the gate electrodes ECL, GSL, WL1 to WLn and SSL and each of the mold insulating layers 110 may have a layered structure in which they extend in parallel with the upper surface of the cell substrate 100. The gate electrodes ECL, GSL, WL1 to WLn and SSL may be sequentially stacked on the cell substrate 100 by being spaced apart from each other by the mold insulating layers 110.

Subsequently, a plurality of channel structures CH passing through the mold structure MS and intersecting the plurality of gate electrodes ECL, GSL, WL1 to WLn and SSL may be formed. In addition, a word line cutting structure WLC passing through the mold structure MS may be formed. A first interlayer insulating layer 121 may be formed on the mold structure MS.

A plurality of cell contacts 153 passing through the first interlayer insulating layer 121, connected to a portion of the plurality of gate electrodes ECL, GSL, WL1 to WLn and SSL may be formed. A through contact 155 passing through the first interlayer insulating layer 121, connected to the peripheral circuit element PT may be formed.

Subsequently, a plurality of first metal patterns 171, a plurality of second metal patterns 172, and a plurality of third metal patterns 173 may be formed. An upper surface 171US of the plurality of first metal patterns 171, an upper surface 172US of the plurality of second metal patterns 172, and an upper surface 173US of the plurality of third metal patterns 173 may be coplanar with one another. The plurality of first metal patterns 171 may be connected to the channel structure CH through first and second bit line contacts 151 and 161. The plurality of second metal patterns 172 may be connected to the plurality of cell contacts 153 through a first via contact 163. The plurality of third metal patterns 173 may be connected to the through contact 155 through a second via contact 165.

Then, a first blocking layer 140 may be formed along an upper surface of the first interlayer insulating layer 121, the upper surface 171US of the plurality of first metal patterns 171, the upper surface 172US of the plurality of second metal patterns 172, and the upper surface of the third metal pattern 173.

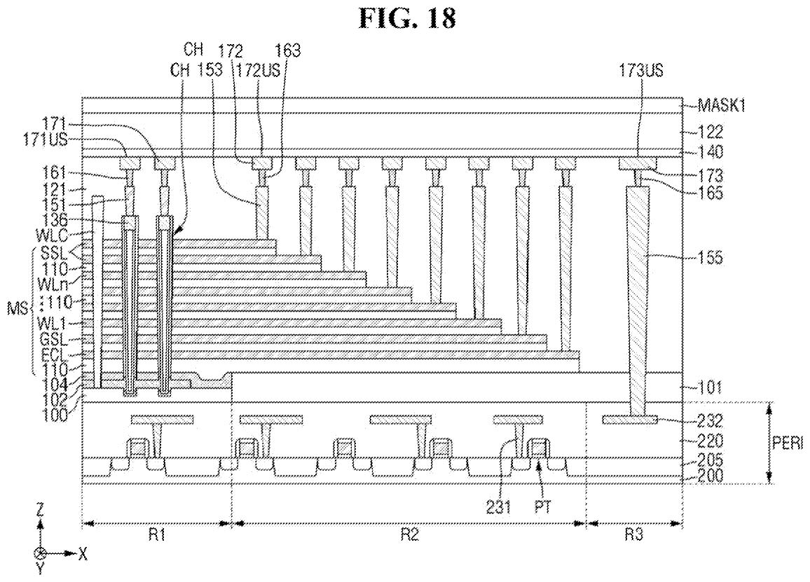

Referring to FIG. 18, a second interlayer insulating layer 122 may be formed on the first blocking layer 140. A first mask layer MASK1 may be formed on the second interlayer insulating layer 122. The first mask layer MASK1 may extend along an upper surface of the second interlayer insulating layer 122. The first mask layer MASK1 may be formed of, e.g., a silicon oxynitride layer (SiON).

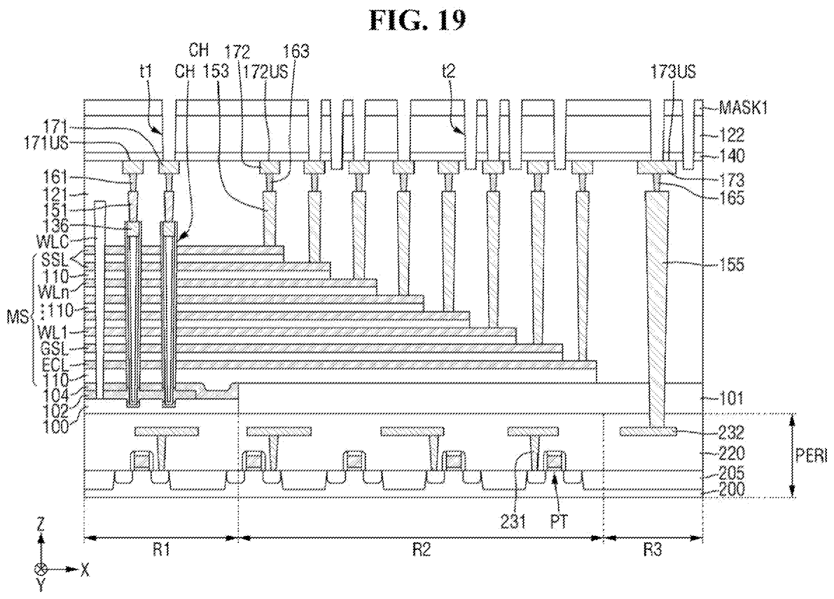

Referring to FIG. 19, a plurality of first trenches t1 and a plurality of second trenches t2 may be formed by removing a portion of the first mask layer MASK1 and a portion of the second interlayer insulating layer 122. The plurality of first trenches t1 may expose a portion of the plurality of first metal patterns 171, a portion of the plurality of second metal patterns 172 and the third metal pattern 173. The plurality of second trenches t2 may expose the first interlayer insulating layer 121. At least a portion of the plurality of second trenches t2 may be in the first interlayer insulating layer 121. A level of a bottom surface of the plurality of first trenches t1 may be higher than that of a bottom surface of the plurality of second trenches t2. This may be due to an etch selectivity of the first to third metal patterns 171, 172 and 173 and the first interlayer insulating layer 121.

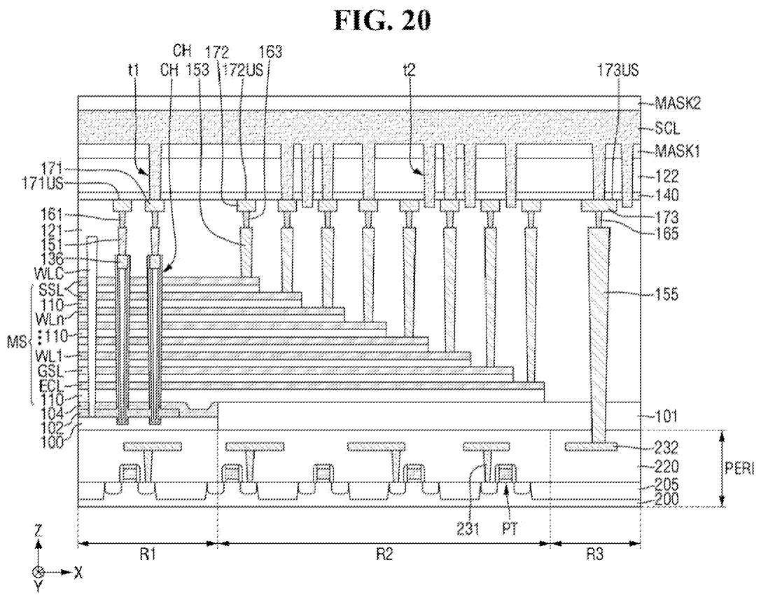

Referring to FIG. 20, a sacrificial layer SCL filling the plurality of first trenches t1 and the plurality of second trenches t2, extending along an upper surface of the first mask layer MASK1, may be formed. In an implementation, the sacrificial layer SCL may be a spin on hardmask (SOH).

Subsequently, a second mask layer MASK2 may be formed on the sacrificial layer SCL. The second mask layer MASK2 may be formed of, e.g., a silicon oxynitride layer (SiON).

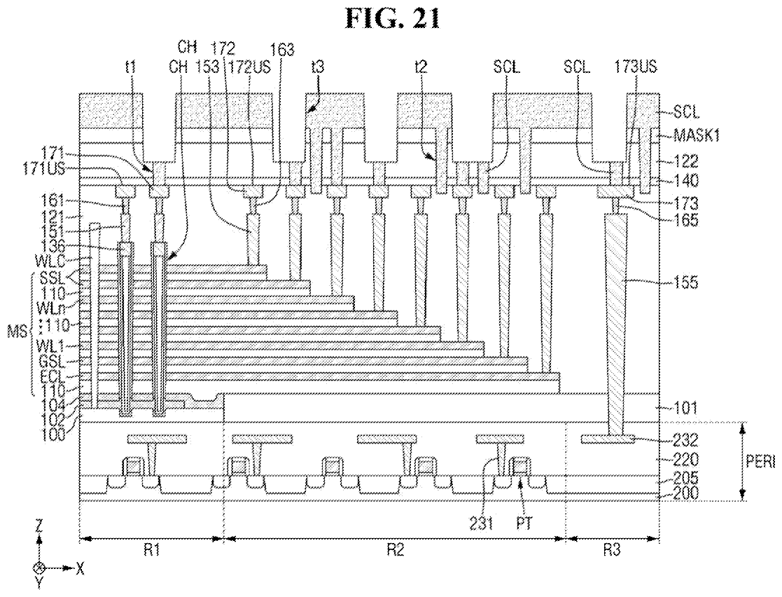

Referring to FIG. 21, a plurality of third trenches t3 may be formed by removing the second mask layer MASK2, a portion of the sacrificial layer SCL, and a portion of the second interlayer insulating layer 122. The plurality of third trenches t3 may overlap the plurality of first trenches t1 in the third direction Z. A width of the plurality of third trenches t3 may be greater than that of the plurality of first trenches t1. A portion of the plurality of third trenches t3 may overlap the second trench t2 in the third direction Z. At least a portion of the plurality of third trenches t3 may not overlap the second trench t2 in the third direction Z.

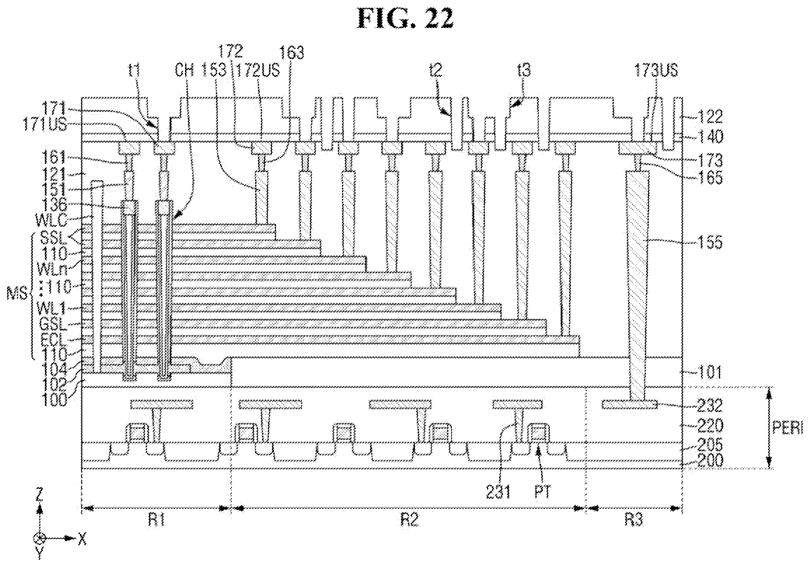

Referring to FIG. 22, the sacrificial layer SCL and the first mask layer MASK1 may be removed. Therefore, the upper surface 171US of the plurality of first metal patterns 171, the upper surface 172US of the plurality of second metal patterns 172, and the upper surface 173US of the third metal pattern 173 may be exposed again. An upper surface of the second interlayer insulating layer 122 may be exposed. In addition, the first interlayer insulating layer 121 may be exposed.

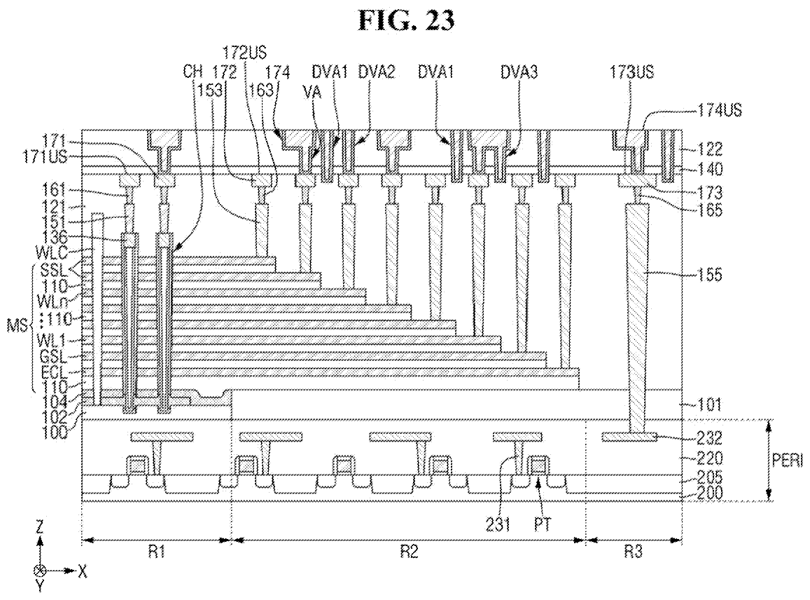

Referring to FIG. 23, a plurality of vias VA, a plurality of first dummy vias DVA1, a second dummy via DVA2, a third dummy via DVA3, and a plurality of fourth metal patterns 174 may be formed. The plurality of vias VA may be formed in the first trench t1. The third dummy via DVA3 may be formed in the first trench t1. The plurality of first dummy vias DVA1 may be formed in the second trench t2. The plurality of fourth metal patterns 174 may be formed in the third trench t3.

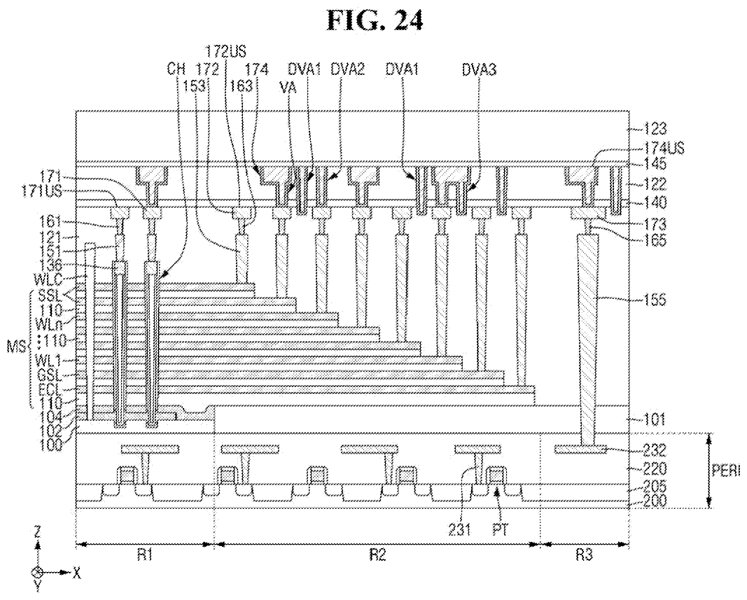

Referring to FIG. 24, a second blocking layer 145 may be formed along the upper surface of the second interlayer insulating layer 122, an upper surface 174US of the fourth metal patterns 174, an upper surface of the plurality of first dummy vias DVA1, and an upper surface of the second dummy via DVA2. A third interlayer insulating layer 123 may be formed on the second blocking layer 145.

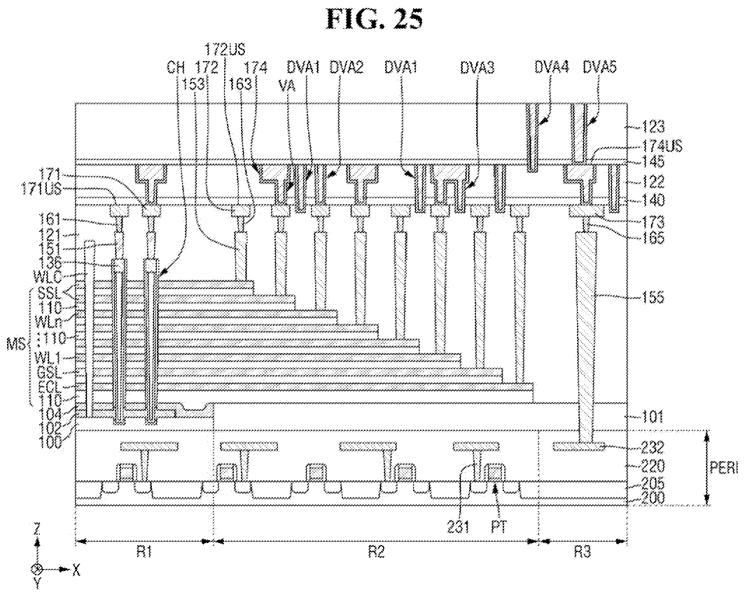

Referring to FIG. 25, a fourth dummy via DVA4 and a fifth dummy via DVA5 passing through the second blocking layer 145 may be formed. The semiconductor memory device according to some embodiments of the present disclosure may include first to third dummy vias DVA1, DVA2, and DVA3 passing through the first blocking layer 140, and fourth and fifth dummy vias DVA4 and DVA5 passing through the second blocking layer 145. Hydrogen may be moved among the first to third interlayer insulating layers 121, 122, and 123 through the first to fifth dummy vias DVA1, DVA2, DVA3, DVA4, and DVA5. The hydrogen may move (e.g., diffuse) from a high concentration to a low concentration. As the hydrogen is moved through the first to fifth dummy vias DVA1, DVA2, DVA3, DVA4, and DVA5, a semiconductor memory device with improved reliability may be implemented.

Hereinafter, an electronic system including a semiconductor memory device according to exemplary embodiments will be described with reference to FIGS. 1 to 6 and FIGS. 26 to 28.

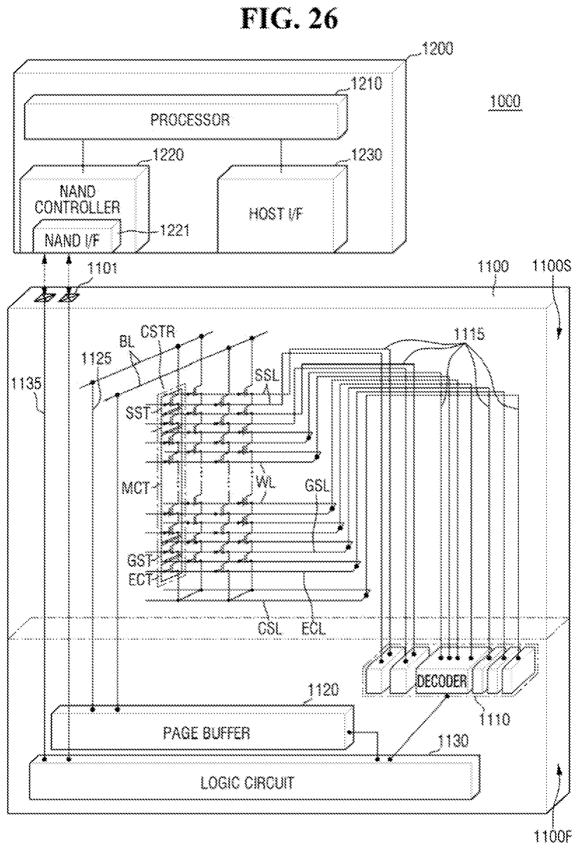

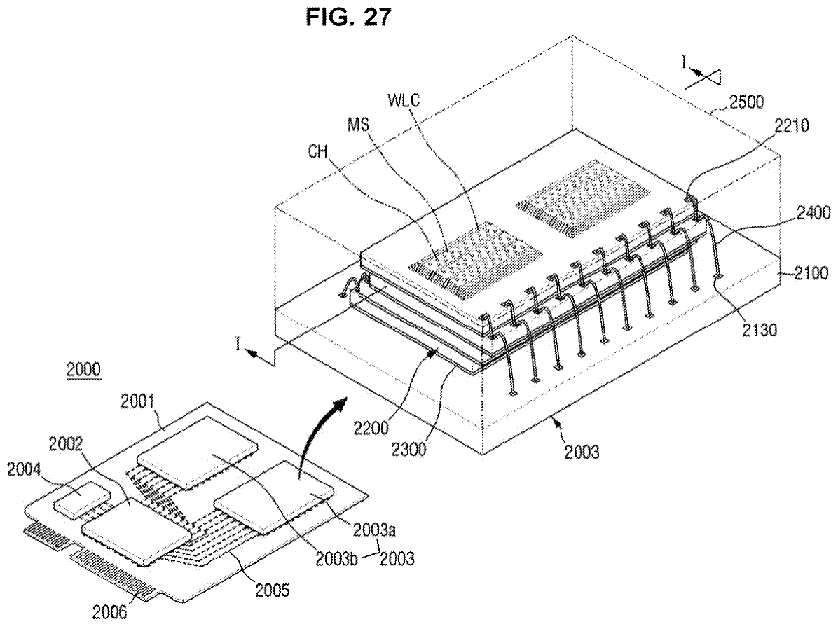

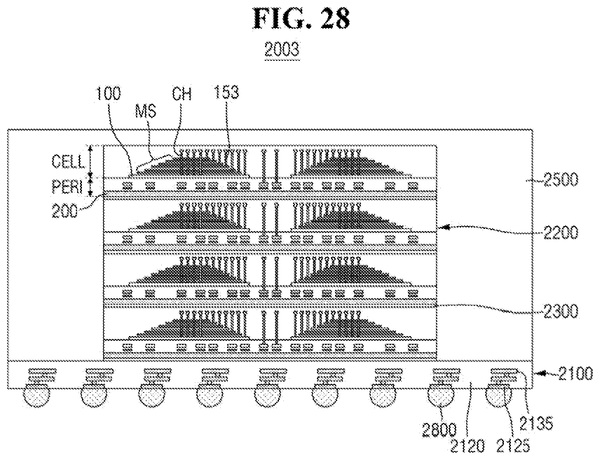

FIG. 26 is an exemplary block diagram illustrating an electronic system according to some embodiments. FIG. 27 is an exemplary perspective view illustrating an electronic system according to some embodiments. FIG. 28 is a schematic cross-sectional view taken along line I-I of FIG. 27.

Referring to FIG. 26, an electronic system 1000 according to some embodiments may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. In an implementation, the electronic system 1000 may be a solid state drive (SSD) device, a universal serial bus (USB), a computing system, a medical device, or a communication device, which includes one or more semiconductor memory devices 1100.

The semiconductor memory device 1100 may be a NAND flash memory device, and may be, e.g., the semiconductor memory device described with reference to FIGS. 1 to 6. The semiconductor memory device 1100 may include a first structure 1100F and a second structure 1100S on the first structure 1100F.

The first structure 1100F may be a peripheral circuit structure that includes a decoder circuit 1110 (e.g., row decoder 33 in FIG. 1), a page buffer 1120 (e.g., page buffer 35 in FIG. 1), and a logic circuit 1130 (e.g., control logic 37 in FIG. 1).

The second structure 1100S may include a common source line CSL, a plurality of bit lines BL, and a plurality of cell strings CSTR, which are described above with reference to FIG. 2. The cell strings CSTR may be connected to the decoder circuit 1110 through a word line WL, at least one string selection line SSL and at least one ground selection line GSL. In addition, the cell strings CSTR may be connected to the page buffer 1120 through the bit lines BL.

In an implementation, the common source line CSL and the cell strings CSTR may be electrically connected to the decoder circuit 1110 through first connection lines 1115 extending from the first structure 1100F to the second structure 1100S.

In an implementation, the bit lines BL may be electrically connected to the page buffer 1120 through second connection lines 1125 extending from the first structure 1100F to the second structure 1100S.

The semiconductor memory device 1100 may perform communication with the controller 1200 through an input/output pad 1101 electrically connected to the logic circuit 1130 (e.g., control logic 37 in FIG. 1). The input/output pad 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In an implementation, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate in accordance with predetermined firmware, and may access the semiconductor memory device 1100 by controlling the NAND controller 1220. The NAND controller 1220 may include a NAND interface 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, or the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 26 to 28, an electronic system 2000 according to some embodiments may include a main board 2001, a main controller 2002 packaged on the main board 2001, one or more semiconductor packages 2003, and a DRAM 2004. The semiconductor package 2003 and the DRAM 2004 may be connected to the main controller 2002 by wiring patterns 2005 formed in the main board 2001.

The main board 2001 may include a connector 2006 that includes a plurality of pins coupled to the external host. The number and arrangement of the plurality of pins in the connector 2006 may be varied depending on the communication interface between the electronic system 2000 and the external host. In an implementation, the electronic system 2000 may perform communication with the external host in accordance with any one of interfaces such as a Universal Serial Bus (USB), a Peripheral Component Interconnect Express (PCI-Express), Serial Advanced Technology Attachment (SATA), and M-Phy for Universal Flash Storage (UFS). In some embodiments, the electronic system 2000 may operate by a power source supplied from the external host through the connector 2006. The electronic system 2000 may further include a power management integrated circuit (PMIC) that distributes the power source supplied from the external host to the main controller 2002 and the semiconductor package 2003.

The main controller 2002 may write data in the semiconductor package 2003 or read the data from the semiconductor package 2003, and may help improve the operating speed of the electronic system 2000.

The DRAM 2004 may be a buffer memory for mitigating a speed difference between the semiconductor package 2003 that is a data storage space and the external host. Also, the DRAM 2004 included in the electronic system 2000 may operate as a kind of a cache memory, and may provide a space for temporarily storing data in a control operation for the semiconductor package 2003. When the DRAM 2004 is included in the electronic system 2000, the main controller 2002 may further include a DRAM controller for controlling the DRAM 2004, in addition to the NAND controller for controlling the semiconductor package 2003.

The semiconductor package 2003 may include a first semiconductor package 2003a and a second semiconductor package 2003b, which are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 on lower surfaces of the respective semiconductor chips 2200, a connection structure 2400 for electrically connecting the semiconductor chips 2200 with the package substrate 2100, and a molding layer 2500 covering the semiconductor chips 2200 and the connection structure 2400 on the package substrate 2100.

The package substrate 2100 may be a printed circuit board that includes package upper pads 2130. Each semiconductor chip 2200 may include an input/output pad 2210. The input/output pad 2210 may correspond to the input/output pad 1101 of FIG. 26.

In an implementation, the connection structure 2400 may be a bonding wire for electrically connecting the input/output pad 2210 with the package upper pads 2130. Therefore, in each of the first semiconductor package 2003a and the second semiconductor package 2003b, the semiconductor chips 2200 may be electrically connected to each other in a bonding wire manner, and may be electrically connected to the package upper pads 2130 of the package substrate 2100. In an implementation, in each of the first semiconductor package 2003a and the second semiconductor package 2003b, the semiconductor chips 2200 may be electrically connected to each other by a connection structure that includes a through silicon via TSV, instead of the connection structure 2400 of the bonding wire manner.

In an implementation, the main controller 2002 and the semiconductor chips 2200 may be included in one package. In an implementation, the main controller 2002 and the semiconductor chips 2200 may be packaged on a separate interposer substrate different from the main board 2001, and the main controller 2002 may be connected with the semiconductor chips 2200 by a wire formed in the interposer substrate.

In an implementation, the package substrate 2100 may be a printed circuit board. The package substrate 2100 may include a package substrate body portion 2120, package upper pads 2130 on an upper surface of the package substrate body portion 2120, lower pads 2125 on a lower surface of the package substrate body portion 2120 or exposed through the lower surface, and internal wires 2135 electrically connecting the package upper pads 2130 with the lower pads 2125 inside the package substrate body portion 2120. The package upper pads 2130 may be electrically connected to the connection structures 2400. The lower pads 2125 may be connected to the wiring patterns 2005 of the main board 2001 of the electronic system 2000 through conductive connectors 2800 as shown in FIG. 26.

Referring to FIGS. 27 and 28, in the electronic system according to some embodiments, each of the semiconductor chips 2200 may include the semiconductor memory device described with reference to FIGS. 1 to 6. In an implementation, each of the semiconductor chips 2200 may include a peripheral circuit structure PERI, and a cell structure CELL stacked on the peripheral circuit structure PERI. In an implementation, the peripheral circuit structure PERI may include the peripheral circuit board 200 and the peripheral circuit element PT, which are described with reference to FIGS. 3 to 6. In an implementation, the cell structure CELL may include the cell substrate 100, the mold structures MS, the channel structure CH, the word line cutting structure WLC, the plurality of first metal patterns 171, the plurality of second metal patterns 172, the first blocking layer 140, and the second blocking layer 145, which are described with reference to FIGS. 3 to 6.

One or more embodiments may provide a semiconductor memory device having improved reliability.

One or more embodiments may provide a method for manufacturing a semiconductor memory device having improved reliability.

One or more embodiments may provide an electronic system that includes a semiconductor memory device having improved reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a substrate including a cell array region and an extension region;
a mold structure including a plurality of gate electrodes sequentially stacked on the cell array region and the extension region of the substrate in a stair shape, and a plurality of mold insulating layers stacked alternately with the plurality of gate electrodes;
a plurality of channel structures on the cell array region of the substrate, the plurality of channel structures intersecting the plurality of gate electrodes and passing through the mold structure;
a plurality of cell contacts respectively connected to the plurality of gate electrodes on the extension region of the substrate;
a first interlayer insulating layer on the mold structure and covering the plurality of channel structures and the plurality of cell contacts;
a plurality of first metal patterns respectively connected to the plurality of channel structures, an upper surface of the plurality of first metal patterns being coplanar with an upper surface of the first interlayer insulating layer;
a plurality of second metal patterns respectively connected to the plurality of cell contacts, an upper surface of the plurality of second metal patterns being coplanar with the upper surface of the plurality of first metal patterns;
a first blocking layer extending along the upper surface of the first interlayer insulating layer, the upper surface of the plurality of first metal patterns, and the upper surface of the plurality of second metal patterns; and
a plurality of first dummy vias passing through the first blocking layer.

2. The semiconductor memory device as claimed in claim 1, wherein at least a portion of the plurality of first dummy vias is in the first interlayer insulating layer.

3. The semiconductor memory device as claimed in claim 1, further comprising a second interlayer insulating layer on the first blocking layer,
wherein at least a portion of the plurality of first dummy vias is in the second interlayer insulating layer.

4. The semiconductor device as claimed in claim 1, further comprising:
a second interlayer insulating layer on the first blocking layer;
a plurality of third metal patterns in the second interlayer insulating layer; and
a plurality of vias below the plurality of third metal patterns and connected to the plurality of first metal patterns and the plurality of second metal patterns.

5. The semiconductor memory device as claimed in claim 4, wherein an upper surface of the plurality of first dummy vias is coplanar with an upper surface of the plurality of third metal patterns.

6. The semiconductor memory device as claimed in claim 4, wherein an upper surface of the plurality of first dummy vias is coplanar with an upper surface of the plurality of vias.

7. The semiconductor memory device as claimed in claim 6, further comprising a plurality of first dummy metal patterns on the plurality of first dummy vias and in the second interlayer insulating layer,
wherein an upper surface of the plurality of first dummy metal patterns is coplanar with an upper surface of the plurality of third metal patterns.

8. The semiconductor memory device as claimed in claim 4, further comprising a plurality of third dummy vias below the plurality of third metal patterns and not connected to the plurality of first metal patterns and the plurality of second metal patterns, and passing through the first blocking layer.

9. The semiconductor memory device as claimed in claim 1, wherein at least a portion of the plurality of first dummy vias is between the plurality of first metal patterns or between the plurality of second metal patterns.

10. The semiconductor memory device as claimed in claim 1, wherein the plurality of first dummy vias are on the extension region of the substrate and not on the cell array region of the substrate.

11. The semiconductor device as claimed in claim 1, further comprising:
a second interlayer insulating layer on the first blocking layer;
a second blocking layer on the second interlayer insulating layer; and
a plurality of second dummy vias passing through the second blocking layer.

12. The semiconductor memory device as claimed in claim 11, wherein at least a portion of the plurality of second dummy vias is in the second interlayer insulating layer.

13. The semiconductor memory device as claimed in claim 11, further comprising a plurality of third metal patterns in the second interlayer insulating layer,
wherein at least a portion of the plurality of second dummy vias is landed on an upper surface of the plurality of third metal patterns.

14. A semiconductor memory device, comprising:
a peripheral circuit structure including a peripheral circuit element; and
a cell structure on the peripheral circuit structure,
wherein the cell structure includes:
a substrate including a cell array region, an extension region, and a pad region;
a mold structure including a plurality of gate electrodes sequentially stacked on the cell array region and the extension region of the substrate in a stair shape, and a plurality of mold insulating layers stacked alternately with the plurality of gate electrodes;
a plurality of channel structures on the cell array region of the substrate, the plurality of channel structures intersecting the plurality of gate electrodes and passing through the mold structure;
a plurality of cell contacts respectively connected to the plurality of gate electrodes on the extension region of the substrate;
a first interlayer insulating layer on the mold structure and covering the plurality of channel structures and the plurality of cell contacts;
a through contact on the pad region of the substrate and connected to the peripheral circuit element by passing through the first interlayer insulating layer;
a plurality of first metal patterns respectively connected to the plurality of channel structures, an upper surface of the plurality of first metal patterns being coplanar with an upper surface of the first interlayer insulating layer;
a plurality of second metal patterns respectively connected to the plurality of cell contacts, an upper surface of the plurality of second metal patterns being coplanar with the upper surface of the plurality of first metal patterns;
a third metal pattern connected to the through contact, an upper surface of the third metal pattern being coplanar with the upper surface of the plurality of first metal patterns;
a first blocking layer extending along the upper surface of the first interlayer insulating layer, the upper surface of the plurality of first metal patterns, the upper surface of the plurality of second metal patterns, and the upper surface of the third metal pattern;
a second interlayer insulating layer on the first blocking layer;
a plurality of fourth metal patterns in the second interlayer insulating layer, an upper surface of the plurality of fourth metal patterns being coplanar with an upper surface of the second interlayer insulating layer;
a plurality of vias below the plurality of fourth metal patterns and connected to the plurality of first metal patterns, the plurality of second metal patterns, and the third metal pattern;
a second blocking layer on the second interlayer insulating layer;
a plurality of first dummy vias passing through the first blocking layer, on the pad region of the substrate and the extension region of the substrate and not on the cell array region of the substrate; and
a plurality of second dummy vias passing through the first blocking layer, and
wherein at least a portion of the plurality of first dummy vias is in the first interlayer insulating layer and in the second interlayer insulating layer.

15. The semiconductor memory device as claimed in claim 14, wherein an upper surface of the plurality of first dummy vias is coplanar with the upper surface of the plurality of fourth metal patterns.

16. The semiconductor memory device as claimed in claim 14, further comprising a plurality of vias below each of the plurality of fourth metal patterns and connected to the plurality of first metal patterns, the plurality of second metal patterns, and the third metal pattern,
wherein an upper surface of the plurality of first dummy vias is coplanar with an upper surface of the plurality of vias.

17. The semiconductor memory device as claimed in claim 14, further comprising a plurality of dummy metal patterns on the plurality of first dummy vias,
wherein an upper surface of the plurality of dummy metal patterns is coplanar with the upper surface of the plurality of fourth metal patterns.

18. The semiconductor memory device as claimed in claim 14, wherein a portion of the plurality of second dummy vias is landed on an upper surface of the plurality of dummy metal patterns.

19. The semiconductor memory device as claimed in claim 14, further comprising a third dummy via below the plurality of fourth metal patterns and not connected to the plurality of first metal patterns, the plurality of second metal patterns, and the third metal pattern, and passing through the first blocking layer,
wherein at least a portion of the third dummy via is in the first interlayer insulating layer.

20. An electronic system, comprising:
a main board;
a semiconductor memory device on the main board; and
a controller electrically connected to the semiconductor memory device on the main board,
wherein the semiconductor memory device includes:
a substrate including a cell array region and an extension region;
a mold structure including a plurality of gate electrodes sequentially stacked on the cell array region and the extension region of the substrate in a stair shape, and a plurality of mold insulating layers stacked alternately with the plurality of gate electrodes;
a plurality of channel structures on the cell array region of the substrate and intersecting the plurality of gate electrodes by passing through the mold structure;
a plurality of cell contacts respectively connected to the plurality of gate electrodes on the substrate of the extension region;
a first interlayer insulating layer on the mold structure and covering the plurality of channel structures and the plurality of cell contacts;
a plurality of first metal patterns respectively connected to the plurality of channel structures, an upper surface of the plurality of first metal patterns being coplanar with an upper surface of the first interlayer insulating layer;
a plurality of second metal patterns respectively connected to the plurality of cell contacts, an upper surface of the plurality of second metal patterns being coplanar with the upper surface of the plurality of first metal patterns;
a first blocking layer extended along the upper surface of the first interlayer insulating layer, the upper surface of the plurality of first metal patterns and the upper surface of the plurality of second metal patterns; and
a plurality of first dummy vias passing through the first blocking layer.
